(19) United States
(12) Patent Application Publication
(10) Pub. No.: US 2023/0141768 A1
(43) Pub. Date: May 11, 2023

(54) DISPLAY PANEL HAVING BLIND HOLE TO ACCOMODATE SIGNALS EXCHANGED WITH UNDER-DISPLAY COMPONENT

(71) Applicant: OTI LUMIONICS INC., Mississauga (CA)

(72) Inventors: Zhibin WANG, Toronto (CA); Michael HELANDER, Toronto (CA); Qi WANG, North York (CA); Yi-Lu CHANG, Scarborough (CA)

(73) Assignee: OTI LUMIONICS INC., Mississauga, ON (CA)

(21) Appl. No.: 17/917,900

(22) PCT Filed: Apr. 9, 2021
(86) PCT No.: PCT/IB2021/052980

§ 371 Date: Oct. 7, 2022

Related U.S. Application Data
(60) Provisional application No. 63/007,851, filed on Apr. 9, 2020.
(60) Provisional application No. 63/107,393, filed on Oct. 29, 2020.
(60) Provisional application No. 63/153,834, filed on Feb. 25, 2021.
(60) Provisional application No. 63/163,453, filed on Mar. 19, 2021.

(51) Int. Cl. H10K 59/65; H10K 59/12

(52) U.S. Cl. CPC H10K 59/65; H10K 59/12

(57) ABSTRACT

A layered panel extends in first and second portions of a lateral aspect, accepting electromagnetic signal(s) through the second portion. The first portion but not the second portion has a closed coating of deposited material. The second portion may comprise a nucleation-inhibiting coating (NIC) and/or a low refractive-index coating. An initial sticking probability for the deposited material of the NIC in the first portion may be less than 0.3, and/or the initial sticking probability for the deposited material on the underlying surface. A higher refractive-index medium may lie on the low refractive index coating. The second portion may comprise at least one particle structure comprised of the deposited material and/or a UVA-absorbing layer. The first portion may comprise emissive region(s) for emitting electromagnetic signal(s). The panel may comprise a substrate and semiconducting layer(s). Each emissive region may comprise first and second electrodes, with the first electrode between the substrate and the semiconducting layer(s), and the semiconducting layer(s) between the first and second electrodes.

### RELATED APPLICATIONS

The present application claims the benefit of priority to: U.S. Provisional Patent Application No. 63/007,851 filed 9 Apr. 2020, U.S. Provisional Patent Application No. 63/107,393 filed 29 Oct. 2020, U.S. Provisional Patent Application No. 63/153,834 filed 25 Feb. 2021 and U.S. Provisional Patent Application No. 63/163,453 filed 19 Mar. 2021, the contents of each of which are incorporated herein by reference in their entirety.

### TECHNICAL FIELD

The present disclosure relates to display panels and in particular to a layered display panel that accepts electromagnetic signal(s) through a blind hole therein.

### BACKGROUND

In an opto-electronic device such as an organic light emitting diode (OLED), at least one semiconducting layer is disposed between a pair of electrodes, such as an anode and a cathode. The anode and cathode are electrically coupled to a power source and respectively generate holes and electrons that migrate toward each other through the at least one semiconducting layer. When a pair of holes and electrons combine, a photon may be emitted.

OLED display panels may comprise a plurality of (sub-) pixels, each of which has an associated pair of electrodes. Various layers and coatings of such panels are typically formed by vacuum-based deposition techniques.

Such display panels may be used, by way of non-limiting example, in electronic devices such as mobile phones.

In some non-limiting applications, it may be desirable to create an opening or blind hole within a display panel to allow an under-display component, which may be a receiver or sensor and/or a transmitter of an electromagnetic signal, including without limitation, an electronic and/or optical signal, to be positioned such that electronic and/or optical signals, including without limitation, light and/or photons, may be exchanged with the under-display component from beyond the device and through the blind hole.

In some non-limiting applications, such a blind hole through the display panel may be achieved by forming, and/or modifying the display panel after formation, such that the region of the blind hole is substantially devoid of components of the display panel that are not substantially transmissive of electromagnetic (EM) signals.

In some non-limiting examples, some of such components, such as thin film transistor (TFT) structure(s) and associated conductive metal lines electrically coupled thereto to selectively drive the (sub-) pixels, may be laid down during the manufacturing process such that they do not lie within the region of the blind hole.

Other components, including without limitation, electrodes, including without limitation, the anode and the cathode, may be provided so that they too lie outside the region of the blind hole.

In some applications, it may be desirable to pattern a conductive coating in a pattern for each (sub-) pixel of the panel across a lateral or aspect thereof, by selective deposition of the conductive coating to form a device feature, such as, without limitation, an electrode and/or a conductive element electrically coupled thereto, during the OLED manufacturing process.

One method for doing so, in some non-limiting applications, involves the interposition of a fine metal mask (FMM) during deposition of a conductive electrode material as, and/or, in some non-limiting examples, electrically coupled to, an electrode, including without limitation, a cathode and/or an anode. However, materials typically used as electrodes have relatively high evaporation temperatures, which impacts the ability to re-use the FMM and/or the accuracy of the pattern that may be achieved, with attendant increases in cost, effort and complexity.

One method for doing so, in some non-limiting examples, involves depositing the electrode material to form the electrode and thereafter removing, including by a laser drilling process, unwanted regions thereof to form the pattern. However, the removal process often involves the creation and/or presence of debris, which may affect the yield of the manufacturing process. In some non-limiting examples, the removal of the electrode may also adversely impact the structural integrity of the display panel.

Further, such methods may not be suitable for use in some applications and/or with some device panels with certain topographical features.

Further, it is often difficult to control the extent of the drilling process, with the result that in some non-limiting examples, not only is the electrode removed, but also one or more of the device layers underlying the electrode.

In some non-limiting examples, because such removal process is used to remove both the anode and the cathode within the region of the blind hole, a consequence of such process is that the at least one semiconducting layer positioned between the anode and the cathode is also removed. In some non-limiting examples, the substrate may also be removed, such that an aperture may be formed by the drilling process. Such hole in active area (HIAA) structure may introduce a number of complications, including without limitation, a reduction in the structural integrity of the device, and potential for oxidation of one or more layers. In some non-limiting examples, such complications may only be mitigated by the expenditure of considerable effort and expense, including the introduction of additional processing steps.

The removal of the at least one semiconducting layer introduces additional complexities. Such semiconducting layer(s) are susceptible to contamination, including without limitation, oxidation, leading to degradation in performance, lifetime and/or yield. As a result, the deposition of such semiconducting layer(s) is typically performed under high vacuum conditions, to minimize the likelihood of such contamination.

Thus, even if such removal process is achieved without substantially introducing debris, additional processing steps may be called for, again under high vacuum conditions, to thereafter seal exposed edges of the at least one semiconducting layer, and in some non-limiting examples, of the anode and cathode, to prevent further contamination through the blind hole region once the display panel is removed from the high vacuum environment.

Such additional processing steps may include, without limitation, adding a layer of material to surround exposed edges of the at least one semiconducting layer and/or the anode and/or cathode along the boundaries thereof with the blind hole region. In some non-limiting examples, the material could comprise a layer of frit glass and/or a thin-film encapsulation (TFE) coating.

United States Patent Application Publication No. 2020/0357871 entitled “Display Device” filed 24 May 2019 by CHUNG, Jin Koo et al. and published 12 Nov. 2020 discloses a display device including a display panel and an optical member. The display panel includes a lower substrate and an upper substrate. The display panel forms a light-transmitting area and a display area near the light-transmitting area. The optical member is adjacent to a rear surface of the display panel and overlaps with a portion corresponding to the light-transmitting area. The display area includes a thin film transistor and an organic light emitting element configured to receive a current from the thin film transistor. The light-transmitting area does not include a metal layer, which is disposed in the display area. The upper substrate and the lower substrate do not have a through-hole structure in the light-transmitting area.

PCT International Patent Application Publication No. WO 2019/199693 entitled “Electronic Device Display for Through-Display Imaging” filed 8 Apr. 2019 by YAZDANDOOST, Mohammad Yeke et al. and published 17 Oct. 2019 discloses systems and methods for through-display imaging. A display includes an imaging aperture defined through an opaque backing. An optical imaging array is aligned with the aperture. Above the aperture, the display is arranged and/or configured for increased optical transmittance. For example, a region of the display above, or adjacent to, the imaging aperture can be formed with a lower pixel density than other regions of the display, thereby increasing inter-pixel distance (e.g. pitch) and increasing an area through which light can traverse the display to reach the optical imaging array.

CN Patent Application Publication No. CN 112234082 entitled “Display and Electronics” filed 10 Oct. 2020 and assigned to Guangdong Oppo Mobile Telecomm Corp. and published 15 Jan. 2021 discloses a display screen and an electronic device. The display screen includes a display layer, a driving layer, and a substrate. The driving layer is arranged below the display layer. The substrate is arranged below the driving layer. The first film layer, the second film layer and the third film layer are stacked in sequence. The surface of the second film layer is formed with an uneven microstructure. The microstructure is used to change the propagation of light after passing through the display layer and the driving layer. Path to reduce or eliminate the diffraction of light passing through the display. An uneven microstructure is formed on the second film layer of the substrate under the driving layer. The microstructure can change the propagation path of light passing through the display layer and the driving layer, that is, it can react to the diffracted light emitted from the driving layer. Interference and disrupt its propagation path, thereby reducing or eliminating the diffraction of light passing through the display screen as a whole to improve the imaging quality of the camera placed under the display screen.

It would be beneficial to provide an improved mechanism for providing a blind hole region in a display panel.

### BRIEF DESCRIPTION OF THE DRAWINGS

Examples of the present disclosure will now be described by reference to the following figures, in which identical reference numerals in different figures indicate identical and/or in some non-limiting examples, analogous and/or corresponding elements and in which:

FIG. 1 is an example energy profile illustrating relative energy states of an adatom absorbed onto a surface according to an example in the present disclosure;

FIG. 2 is a schematic diagram illustrating the formation of a film nucleus according to an example in the present disclosure;

FIG. 3A is a simplified block diagram, from a cross-sectional aspect, of an example display panel having a plurality of layers, comprising a first portion and a blind hole region in a second portion of a lateral aspect, according to an example in the present disclosure;

FIG. 3B is a schematic diagram showing faces of example user devices comprising the device of FIG. 3A as a display thereof and example positions of blind hole regions therein according to an example in the present disclosure;

FIG. 3C is a simplified block diagram, from a cross-sectional aspect, of an example version of the user device; according to an example in the present disclosure;

FIG. 4 is a simplified block diagram, from a cross-sectional aspect, of a part of the device of FIG. 3A, showing an emissive region and surrounding non-emissive regions; and

FIG. 5 is a simplified block diagram, from a cross-sectional aspect, of an example of a part of the device of FIG. 3A, showing various layers of the display thereof, including the blind hole region therein, according to an example in the present disclosure.

In the present disclosure, a reference numeral having one or more numeric values (including without limitation, in subscript) and/or lower-case alphabetic character(s) appended thereto may be considered to refer to a particular instance, and/or subset thereof, of the element or feature described by the reference numeral. Reference to the reference numeral without reference to the appended value(s) and/or character(s) may, as the context dictates, refer generally to the element(s) or feature(s) described by the reference numeral and/or to the set of all instances described thereby.

In the present disclosure, for purposes of explanation and not limitation, specific details are set forth in order to provide a thorough understanding of the present disclosure, including, without limitation, particular architectures, interfaces and/or techniques. In some instances, detailed descriptions of well-known systems, technologies, components, devices, circuits, methods and applications are omitted so as not to obscure the description of the present disclosure with unnecessary detail.

Further, it will be appreciated that block diagrams reproduced herein can represent conceptual views of illustrative components embodying the principles of the technology.

Accordingly, the system and method components have been represented where appropriate by conventional symbols in the drawings, showing only those specific details that are pertinent to understanding the examples of the present disclosure, so as not to obscure the disclosure with details that will be readily apparent to those of ordinary skill in the art having the benefit of the description herein.

Any drawings provided herein may not be drawn to scale and may not be considered to limit the present disclosure in any way.

Any feature or action shown in dashed outline may in some examples be considered as optional.

### SUMMARY

It is an object of the present disclosure to obviate or mitigate at least one disadvantage of the prior art.

The present disclosure discloses a layered display panel that extends in first and second portions of at least one lateral aspect and accepts electromagnetic (EM) signal(s) through the second portion. A closed coating of a deposited material is on a layer surface in the first portion. The second portion has no such closed coating(s). The second portion may comprise a nucleation-inhibiting coating (NIC). An initial sticking probability for depositing the deposited material onto the NIC surface in the first portion may be substantially less than 0.3, and/or the initial sticking probability for depositing the deposited material onto the layer surface. The second portion may comprise at least one particle structure comprised of the deposited material. The second portion may comprise a UVA-absorbing layer. The second portion may comprise a low-index coating and a high-index medium extending along a surface thereof, wherein a refractive index of the low-index coating may be less than a refractive index of the high-index medium. The first portion may comprise emissive region(s) for emitting EM signal(s). The panel may comprise a substrate and semiconducting layer(s). Each emissive region may comprise first and second electrodes. The first electrode lies between the substrate and the semiconducting layer(s), and the semiconducting layer(s) lie between the first and second electrodes.

According to a broad aspect of the present disclosure, there is disclosed a display panel having a plurality of layers and extending in a first portion and a second portion of at least one lateral aspect defined by a lateral axis, the panel adapted to accept at least one electromagnetic (EM) signal through the second portion, at an angle relative to the layers, for exchange with at least one under-display component, the panel comprising at least one closed coating of a deposited material disposed on an exposed layer surface of the panel in the first portion; wherein the second portion is substantially devoid of a closed coating of the deposited material.

In some non-limiting examples, the at least one under-display component may comprise at least one of: a receiver adapted to receive; and a transmitter adapted to emit; the at least one EM signal passing through the panel beyond the user device.

According to a broad aspect of the present disclosure, there is disclosed a display panel having a plurality of layers and extending in a first portion and second portion of at least one lateral aspect defined by a lateral axis, the panel adapted to accept at least one electromagnetic (EM) signal through the second portion, at an angle relative to the layers, comprising at least one closed coating of a deposited material disposed on an exposed layer surface of the panel in the first portion; wherein the second portion is substantially devoid of a closed coating of the deposited material.

In some non-limiting examples, the panel may further comprise a nucleation-inhibiting coating (NIC) on the exposed layer surface thereof in the second portion, wherein an initial sticking probability for depositing the deposited material onto a surface of the NIC in the first portion may be substantially less than at least one of: 0.3, and the initial sticking probability for depositing the deposited material onto the exposed layer surface.

In some non-limiting examples, the second portion may comprise at least one particle structure comprised of the deposited material.

In some non-limiting examples, the second portion may comprise a UVA-absorbing layer.

In some non-limiting examples, the panel further comprises a low-index coating disposed on the exposed layer surface of the panel in the second portion and a high-index medium extending along a surface of the low-index coating, wherein a refractive index of the low-index coating is less than a refractive index of the high-index medium.

In some non-limiting examples, the deposited material may comprise at least one of silver (Ag) and ytterbium (Yb).

In some non-limiting examples, an average film thickness of the at least one closed coating may be between about 5-80 nm.

In some non-limiting examples, the first portion may comprise at least one emissive region for emitting an EM signal at an angle relative to the layers.

In some non-limiting examples, the panel may further comprise a substrate; and at least one semiconducting layer disposed thereon; and wherein: each emissive region comprises a first electrode and a second electrode, the first electrode is disposed between the substrate and the at least one semiconducting layer, and the at least one semiconducting layer is disposed between the first electrode and the second electrode.

In some non-limiting examples, the second electrode may comprise the at least one closed coating of the deposited material.

In some non-limiting examples, the exposed layer surface of the panel may be an exposed layer surface of the at least one semiconducting layer. In some non-limiting examples, the substrate may extend substantially continuously across both the first portion and the second portion. In some non-limiting examples, the at least one semiconducting layer may extend substantially continuously across both the first portion and the second portion.

In some non-limiting examples, the first portion may comprise a plurality of emissive regions. In some non-limiting examples, the first portion may comprise at least one non-emissive region between adjacent emissive regions. In some non-limiting examples, the second portion may be substantially devoid of any emissive regions.

In some non-limiting examples, the panel may further comprise at least one covering layer disposed on an exposed layer surface of the at least one closed coating in the first portion and on an exposed layer surface of the panel in the second portion.

According to a broad aspect of the present disclosure, there is disclosed a user device comprising: a display panel having a plurality of layers and extending in a first portion and a second portion of at least one lateral aspect defined by a lateral axis; and at least one under-display component adapted to exchange at least one electromagnetic (EM) signal through the second portion of the panel at an angle relative to the layers; wherein the panel comprises at least one closed coating of a deposited material disposed on an exposed layer surface of the panel in the first portion; and wherein the second portion is substantially devoid of a closed coating of the deposited coating.

Examples have been described above in conjunction with aspects of the present disclosure upon which they can be implemented. Those having ordinary skill in the relevant art will appreciate that examples may be implemented in conjunction with the aspect with which they are described, but may also be implemented with other examples of that or another aspect. When examples are mutually exclusive, or are otherwise incompatible with each other, it will be apparent to those having ordinary skill in the relevant art. Some examples may be described in relation to one aspect, but may also be applicable to other aspects, as will be apparent to those having ordinary skill in the relevant art.

Some aspects or examples of the present disclosure may provide a layered display panel that extends in first and second portions of at least one lateral aspect and accepts EM signal(s) through the second portion. A closed coating of a deposited material is on a layer surface in the first portion. The second portion has no such closed coating(s).

### DESCRIPTION

The present disclosure relates generally to display panels, which may comprise electronic devices, and more specifically, opto-electronic devices. An opto-electronic device generally encompasses any device that converts electrical signals into photons and vice versa.

Those having ordinary skill in the relevant art will appreciate that, while the present disclosure is directed to opto-electronic devices, the principles thereof may be applicable to any panel having a plurality of layers, through which electromagnetic (EM) signals may pass, entirely or partially, at an angle relative to a plane of at least one of the layers.

### Thin Film Formation

The formation of thin films during vapor deposition on an exposed layer surface 11 of an underlying material involves processes of nucleation and growth.

During initial stages of film formation, a sufficient number of vapor monomers (which in some non-limiting examples may be molecules and/or atoms of a deposited material in vapor form) may typically condense from a vapor phase to form initial nuclei on the exposed layer surface 11 presented of an underlying layer. As vapor monomers continue to impinge on such surface, a characteristic size S1 and/or deposited density of these initial nuclei may increase to form small particles. Non-limiting examples of a dimension to which such characteristic size S1 refers may include a height, width, length, and/or diameter of such particle.

After reaching a saturation island density, adjacent particle typically will start to coalesce, increasing an average characteristic size S1 of such particles, while decreasing a deposited density thereof.

With continued vapor deposition of monomers, coalescence of adjacent particles may continue until a substantially closed coating may eventually be deposited on an exposed layer surface 11 of an underlying material. The behaviour, including optical effects caused thereby, of such closed coating may be generally relatively uniform, consistent and unsurprising.

There may be at least three basic growth modes for the formation of thin films, in some non-limiting examples, culminating in a closed coating: 1) island (Volmer-Weber), 2) layer-by-layer (Frank-van der Merwe), and 3) Stranski-Krastanov.

Island growth may typically occur when stale clusters of monomers nucleate on an exposed layer surface 11 and grow to form discrete islands. This growth mode may occur when the interaction between the monomers is stronger than that between the monomers and the surface.

The nucleation rate may describe how many nuclei of a given size (where the free energy does not push a cluster of such nuclei to either grow or shrink) (“critical nuclei”) on a surface per unit time. During initial stages of film formation, it may be unlikely that nuclei will grow from direct impingement of monomers on the surface, since the deposited density of nuclei is low, and thus the nuclei may cover a relatively small fraction of the surface (e.g. there are large gaps/spaces between neighboring nuclei). Therefore, the rate at which critical nuclei may grow may typically depend on the rate at which adatoms (e.g. adsorbed monomers) on the surface migrate and attach to nearby nuclei.

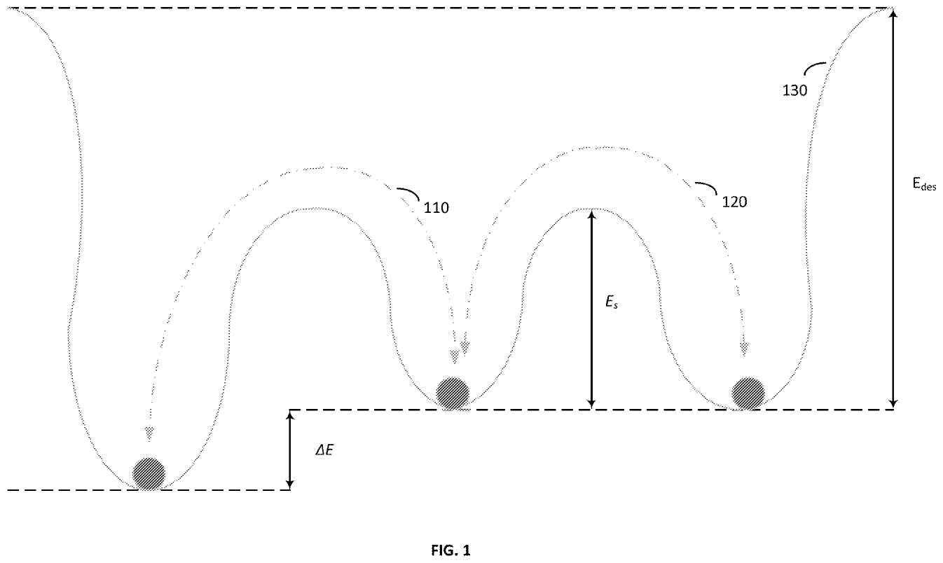

An example of an energy profile of an adatom adsorbed onto an exposed layer surface 11 of an underlying material is illustrated in FIG. 1. Specifically, FIG. 1 illustrates example qualitative energy profiles corresponding to: an adatom escaping from a local low energy site (110); diffusion of the adatom on the exposed layer surface 11 (120); and desorption of the adatom (130).

In 110, the local low energy site may be any site on the exposed layer surface 11 of an underlying layer, onto which an adatom will be at a lower energy. Typically, the nucleation site may comprise a defect and/or an anomaly on the exposed layer surface 11, including without limitation, a ledge, a step edge, a chemical impurity, a bonding site, and/or a kink (“heterogeneity”).

Sites of substrate heterogeneity may increase E_{des}, leading to a higher deposited density of nuclei observed at such sites. Also, impurities or contamination on a surface may also increase E_{des}, leading to a higher deposited density of nuclei. For vapor deposition processes, conducted under high vacuum conditions, the type and deposited density of contaminants on a surface may be affected by a vacuum pressure and a composition of residual gases that make up that pressure.

Once the adatom is trapped at the local low energy site, there may typically, in some non-limiting examples, be an energy barrier before surface diffusion takes place. Such energy barrier may be represented as AE in FIG. 1. In some non-limiting examples, if the energy barrier AE to escape the local low energy site is sufficiently large, the site may act as a nucleation site.

In 120, the adatom may diffuse on the exposed layer surface 11. By way of non-limiting examples, in the case of localized absorbates, adatoms may tend to oscillate near a minimum of the surface potential and migrate to various neighboring sites until the adatom is either desorbed, and/or is incorporated into growing islands formed by a cluster of adatoms and/or a growing film. In FIG. 1, the activation energy associated with surface diffusion of adatoms may be represented as Eₛ.

In 130, the activation energy associated with desorption of the adatom from the surface may be represented as E_{des}. Those having ordinary skill in the relevant art will appreciate that any adatoms that are not desorbed may remain on the exposed layer surface 11. By way of non-limiting example, such adatoms may diffuse on the exposed layer surface 11, become part of a cluster of adatoms that form islands on the exposed layer surface 11, and/or be incorporated as part of a growing film and/or coating.

After adsorption of an adatom on a surface, the adatom may either desorb from the surface, or may migrate some distance on the surface before either desorbing, interacting with other adatoms to form a small cluster, or attaching to a growing nucleus. An average amount of time that an adatom remains on the surface after initial adsorption may be given by:

$${τ}_{s} = \frac{1}{v} exp ( \frac{{E}_{des}}{kT} )$$

In the above equation, v is a vibrational frequency of the adatom on the surface, k is the Boltzmann constant, Tis temperature, and E_{des} is an energy involved to desorb the adatom from the surface. From this equation it may be noted that the lower the value of E_{des}, the easier it may be for the adatom to desorb from the surface, and hence the shorter the time the adatom may remain on the surface. A mean distance an adatom can diffuse may be given by,

$$X = {a}_{0} exp ( \frac{{E}_{des} - {E}_{s}}{2 kT} )$$

where α₀ is a lattice constant and Eₛ is an activation energy for surface diffusion. For low values of E_{des} and/or high values of Eₛ, the adatom may diffuse a shorter distance before desorbing, and hence may be less likely to attach to growing nuclei or interact with another adatom or cluster of adatoms.

During initial stages of formation of a deposited layer of particles, adsorbed adatoms may interact to form particles, with a critical concentration of particles per unit area being given by:

$$\frac{{N}_{i}}{{n}_{0}} = {\vert \frac{{N}_{1}}{{n}_{0}} \vert}^{i} exp ( \frac{{E}_{i}}{kT} )$$

where Eᵢ is an energy involved to dissociate a critical cluster containing i adatoms into separate adatoms, no is a total deposited density of adsorption sites, and Nᵢ is a monomer deposited density given by:

N₁=\dot{R}τₛ

where \dot{R} is a vapor impingement rate. Typically, l may depend on a crystal structure of a material being deposited and may determine the critical particle size to form a stable nucleus.

A critical monomer supply rate for growing particles may be given by the rate of vapor impingement and an average area over which an adatom can diffuse before desorbing:

$$\dot{R} {X}^{2} = {α}_{0}^{2} exp ( \frac{{E}_{des} - {E}_{s}}{kT} )$$

The critical nucleation rate may thus be given by the combination of the above equations:

$${\dot{N}}_{i} = \dot{R} {α}_{0}^{2} {{n}_{0} ( \frac{\dot{R}}{{vn}_{0}} )}^{i} exp ( \frac{( i + 1 ) {E}_{des} - {E}_{s} + {E}_{i}}{kT} )$$

From the above equation, it may be noted that the critical nucleation rate may be suppressed for surfaces that have a low desorption energy for adsorbed adatoms, a high activation energy for diffusion of an adatom, are at high temperatures, and/or are subjected to vapor impingement rates.

Under high vacuum conditions, a flux of molecules that impinge on a surface (per cm²-sec) may be given by:

$$Φ = 3.513 \times {10}^{22} \frac{P}{MT}$$

where P is pressure, and M is molecular weight. Therefore, a higher partial pressure of a reactive gas, such as H₂O, may lead to a higher deposited density of contamination on a surface during vapor deposition, leading to an increase in E_{des} and hence a higher deposited density of nuclei.

In the present disclosure, “nucleation-inhibiting” may refer to a coating, material, and/or a layer thereof, that has a surface that exhibits an initial sticking probability S₀ for deposition of a deposited material 426 (including without limitation, a deposited coating 325, which in some non-limiting examples, may be formed thereof), thereon, that is close to 0, including without limitation, less than about 0.3, such that the deposition of the deposited material 426 (and/or deposited coating 325) on such surface may be inhibited.

In the present disclosure, “nucleation-promoting” may refer to a coating, material, and/or a layer thereof, that has a surface that exhibits an initial sticking probability S₀ for deposition of a deposited material 426 (including without limitation, a deposited coating 325, which in some non-limiting examples, may be formed thereof) thereon, that is close to 1, including without limitation, greater than about 0.7, such that the deposition of the deposited material 426 (and/or deposited coating 325) on such surface may be facilitated.

Without wishing to be bound by a particular theory, it may be postulated that the shapes and sizes of such nuclei and the subsequent growth of such nuclei into particles and thereafter into a thin film may depend upon a number of factors, including without limitation, interfacial tensions between the vapor, the surface, and/or the condensed film nuclei.

One measure of a nucleation-inhibiting and/or nucleation-promoting property of a surface may be the initial sticking probability S₀ of the surface for a given deposited material 426 from which a (conductive) deposited coating 325 is comprised.

In some non-limiting examples, the sticking probability S may be given by:

$$S = \frac{{N}_{ads}}{{N}_{total}}$$

where N_{ads} is a number of adatoms that remain on an exposed layer surface 11 (that is, are incorporated into a film) and Nₜₒₜₐₗ is a total number of impinging monomers on the surface. A sticking probability of S equal to 1 may indicate that all monomers that impinge on the surface are adsorbed and subsequently incorporated into a growing film. A sticking probability S equal to 0 may indicate that all monomers that impinge on the surface are desorbed and subsequently no film is formed on the surface.

A sticking probability of S of a deposited material on various surfaces may be evaluated using various techniques of measuring the sticking probability S, including without limitation, a dual quartz crystal microbalance (QCM) technique as described by Walker et al., J. Phys. Chem. C 2007, 111, 765 (2006).

As the deposited density of a deposited material 426 (including without limitation, a deposited coating 325 formed thereby) increases (e.g., increasing average film thickness a), a sticking probability S may change.

An initial sticking probability S₀ may therefore be specified as a sticking probability S of a surface prior to the formation of any significant number of critical nuclei. One measure of an initial sticking probability S₀ may involve a sticking probability S of a surface for a deposited material 426 during an initial stage of deposition thereof, where an average film thickness d of the deposited material 426 across the surface is at or below a threshold value. In the description of some non-limiting examples, a threshold value for an initial sticking probability S₀ may be specified as, by way of non-limiting examples, 1 nm. An average sticking probability S may then be given by:

S̅=S₀(1−A_{nuc})+S_{nuc}(A_{nuc})

where S_{nuc} is a sticking probability S of an area covered by particles, and A_{nuc} is a percentage of an area of a substrate surface covered by particles.

By way of non-limiting example, a low initial sticking probability S₀ may increase with increasing average film thickness d. This may be understood based on a difference in sticking probability S between an area of a surface with no particles, by way of non-limiting example, a bare substrate 10, and an area with a high deposited density. By way of non-limiting example, a monomer that impinges on a surface of a particle may have a sticking probability S that approaches 1.

Based on the energy profiles 110, 120, 130 shown in FIG. 1, it may be postulated that materials that exhibit relatively low activation energy for desorption (E_{des}), and/or relatively high activation energy for surface diffusion (Eₛ), may be deposited as a NIC material 416, and may be suitable for use in various applications.

Without wishing to be bound by a particular theory, it may be postulated that, in some non-limiting examples, the relationship between various interfacial tensions present during nucleation and growth may be dictated according to Young's equation in capillarity theory:

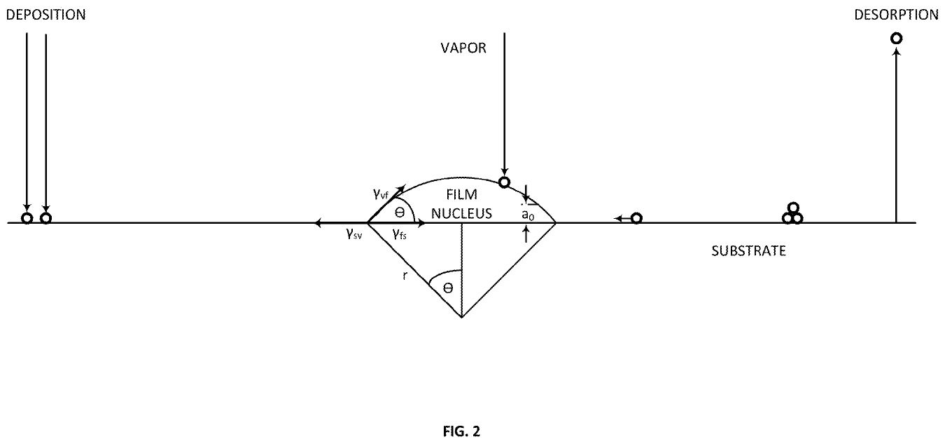

γₛᵥ=γ_{fs}+γ_{vf} cos θ

where γₛᵥ corresponds to the interfacial tension between the substrate 10 and vapor, γ_{fs} corresponds to the interfacial tension between the deposited material 426, and/or the thin film deposited coating 325 formed thereby, and the substrate 10, γ_{vf} corresponds to the interfacial tension between the vapor and the film, and θ is the film nucleus contact angle. FIG. 2 illustrates the relationship between the various parameters represented in this equation.

On the basis of Young's equation, it may be derived that, for island growth, the film nucleus contact angle θ may be greater than 0 and therefore γ_{sy}<γ_{fs}+γ_{vf}.

For layer growth, where the deposited material 426 “wets” the substrate 10, the nucleus contact angle θ may be equal to 0, and therefore γ_{sy}=γ_{fs}+γ_{vf}.

For Stranski-Krastanov (S-K) growth, where the strain energy per unit area of the film overgrowth is large with respect to the interfacial tension between the vapor and the deposited material 426, γ_{sy}>γ_{fs}+γ_{vf}.

Without wishing to be bound by any particular theory, it may be postulated that the nucleation and growth mode of a deposited material 426 (including without limitation, a deposited coating 325 formed thereby) at an interface between the NIC material 416 and the exposed layer surface 11 of the substrate 10, may follow the island grown model, where θ>0.

Particularly in cases where the NIC material 416 exhibits a relatively low initial sticking probability S₀ (in some non-limiting examples, under the conditions identified in the dual QCM technique described by Walker et al) towards the deposited material 426, there may be a relatively high thin film contact angle θ of the deposited material 426.

On the contrary, when a deposited material 426 may be selectively deposited on a surface without the use of a NIC material 416, by way of non-limiting example, by employing a shadow mask, the nucleation and growth mode of such deposited material 426 may differ. In particular, it has been observed that a coating formed using a shadow mask patterning process may, at least in some non-limiting examples, exhibit relatively low thin film contact angle θ of less than about 100.

It has now been found, somewhat surprisingly, that in some non-limiting examples, a (nucleation-inhibiting) NIC 410 (and/or the NIC material 416 of which it is comprised) may exhibit a relatively low critical surface tension.

Those having ordinary skill in the relevant art will appreciate that a “surface energy” of a coating, layer, and/or a material constituting such coating and/or layer, may generally corresponding to a critical surface tension of the coating, layer, and/or material. According to some models of surface energy, the critical surface tension of a surface may correspond substantially to the surface energy of such surface.

Generally, a material with a low surface energy may exhibit low intermolecular forces. Generally, a material with low intermolecular forces may readily crystallize or undergo other phase transformation at a lower temperature in comparison to another material with high intermolecular forces. In at least some applications, a material that readily crystallizes or undergoes other phase transformations at relatively low temperatures may be detrimental to the long-term performance, stability, reliability, and/or lifetime of the device.

Without wishing to be bound by a particular theory, it may be postulated that certain low energy surfaces may exhibit relatively low initial sticking probabilities S₀ and may thus be suitable for forming the NIC material 416.

Without wishing to be bound by any particular theory, it may be postulated that, especially for low surface energy surfaces, the critical surface tension may be positively correlated with the surface energy. For example, a surface exhibiting a relatively low critical surface tension may also exhibit a relatively low surface energy, and a surface exhibiting a relatively high critical surface tension may also exhibit a relatively high surface energy.

In reference to Young's equation described above, a lower surface energy may result in a greater contact angle θ, while also lowering the γₛᵥ, thus enhancing the likelihood of such surface having low wettability and low initial sticking probability S₀ with respect to the deposited material 426.

The critical surface tension values, in various non-limiting examples, herein may correspond to such values measured at around normal temperature and pressure (NTP), which in some non-limiting examples, may correspond to a temperature of 20° C., and an absolute pressure of 1 atm. In some non-limiting examples, the critical surface tension of a surface may be determined according to the Zisman method, as further detailed in Zisman, W. A., “Advances in Chemistry” 43 (1964), p. 1-51.

In some non-limiting examples, the exposed layer surface 11 of the NIC material 416 may exhibit a critical surface tension of less than: about 20 dyne/cm, about 19 dyne/cm, about 18 dyne/cm, about 17 dyne/cm, about 16 dyne/cm, about 15 dyne/cm, about 13 dyne/cm, about 12 dyne/cm, or about 11 dyne/cm.

In some non-limiting examples, the exposed layer surface 11 of the NIC material 416 may exhibit a critical surface tension of greater than: about 6 dyne/cm, about 7 dyne/cm, about 8 dyne/cm, about 9 dyne/cm, or about 10 dyne/cm.

Those having ordinary skill in the relevant art will appreciate that various methods and theories for determining the surface energy of a solid are known. By way of non-limiting example, the surface energy may be calculated and/or derived based on a series of measurements of contact angle θ, in which various liquids are brought into contact with a surface of a solid to measure the contact angle θ between the liquid-vapor interface and the surface. In some non-limiting examples, the surface energy of a solid surface may be equal to the surface tension of a liquid with the highest surface tension that completely wets the surface. By way of non-limiting example, a Zisman plot may be used to determine the highest surface tension value that would result in a contact angle θ of 0° of the surface.

Without wishing to be bound by a particular theory, it may be postulated that, in some non-limiting examples, the contact angle θ of the deposited coating 325 may be determined, based at least partially on the properties (including, without limitation, initial sticking probability S₀) of the NIC material 416 onto which the deposited material 426 is deposited. Accordingly, patterning materials 316 that allow selective deposition of deposited materials 426 exhibiting relatively high contact angles θ may provide some benefit.

As would be appreciated by persons skilled in the art, a NIC material 416, exhibiting a combination of: (i) a relatively low critical surface tension, for example of no more than: about 19 dynes/cm or about 15 dynes/cm; (ii) a relatively low refractive index n in the visible wavelength range, for example of no more than: about 1.45 or about 1.35; and (iii) a relatively low attenuation coefficient in the visible wavelength range, for example of no more than: about 0.05 or about 0.01, may be suitable to pattern a metallic deposited material 426 while also allowing a significant degree of light transmission, especially if it forms an interface with a layer having a high critical surface tension for example greater than: about 30 dyne/cm or about 300 dyne/cm.

Those having ordinary skill in the relevant art will appreciate that various methods may be used to measure a contact angle θ, including without limitation, the static and/or dynamic sessile drop method and the pendant drop method.

In some non-limiting examples, the activation energy for desorption (E_{des}) (in some non-limiting examples, at a temperature T of about 300K) may be less than: about 2 times, about 1.5 times, about 1.3 times, about 1.2 times, about 1.0 times, about 0.8 times, or about 0.5 times, the thermal energy (k_{B}T). In some non-limiting examples, the activation energy for surface diffusion (Eₛ) (in some non-limiting examples, at a temperature T of about 300K) may be greater than: about 1.0 times, about 1.5 times, about 1.8 times, about 2 times, about 3 times, about 5 times, about 7 times, or about 10 times, the thermal energy (k_{B}T).

Without wishing to be bound by a particular theory, it may be postulated that, during thin film nucleation and growth of a deposited material 426 at and/or near an interface between the exposed layer surface 11 of the underlying layer and the NIC material 416, a relatively high contact angle θ between the edge of the deposited material 426 and the underlying layer may be observed due to the inhibition of nucleation of the solid surface of the deposited material 426 by the NIC 410. Such nucleation-inhibiting property may be driven by minimization of surface energy between the underlying layer, thin film vapor and the NIC 410.

One measure of a nucleation-inhibiting and/or nucleation-promoting property of a surface may be an initial deposition rate of a given (electrically conductive) deposited material 426, on the surface, relative to an initial deposition rate of the same conductive deposited material 426 on a reference surface, where both surfaces are subjected to and/or exposed to an evaporation flux of the (conductive) deposited material 426.

### Display Panel

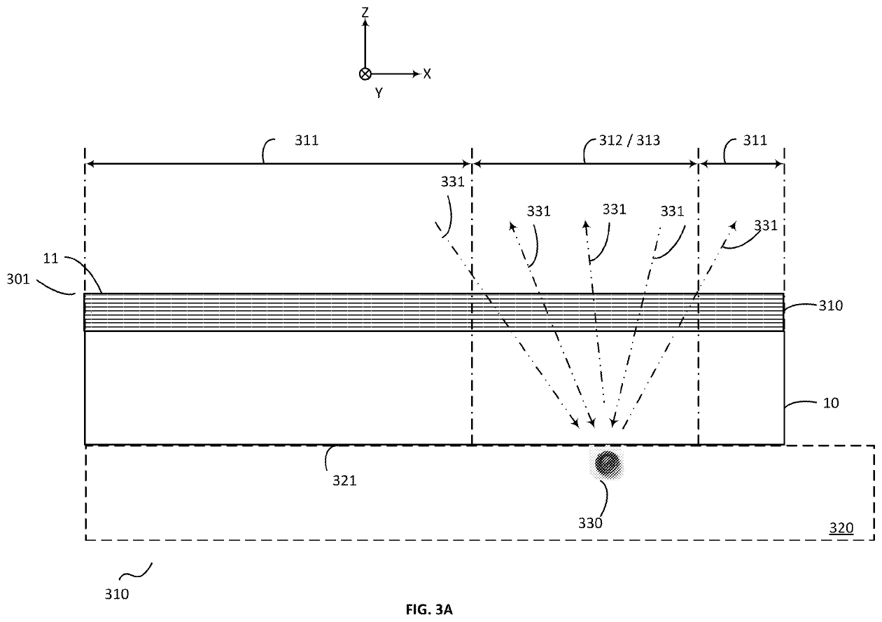

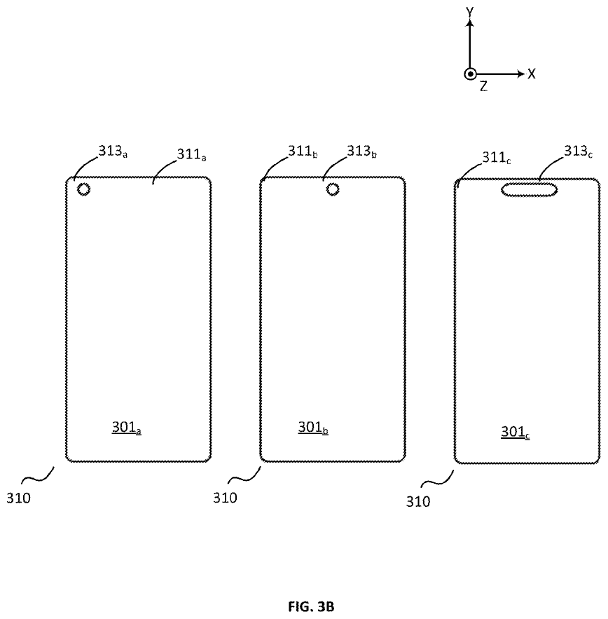

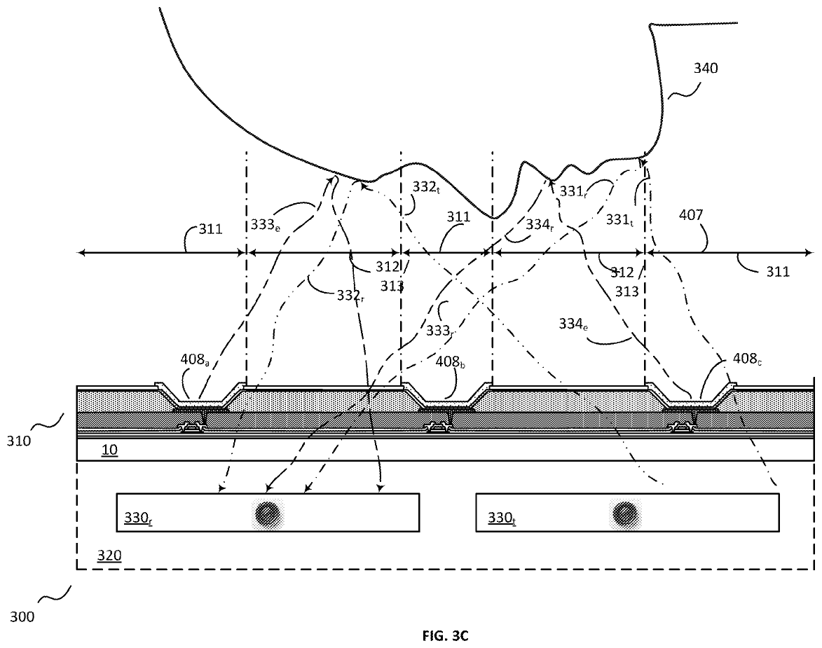

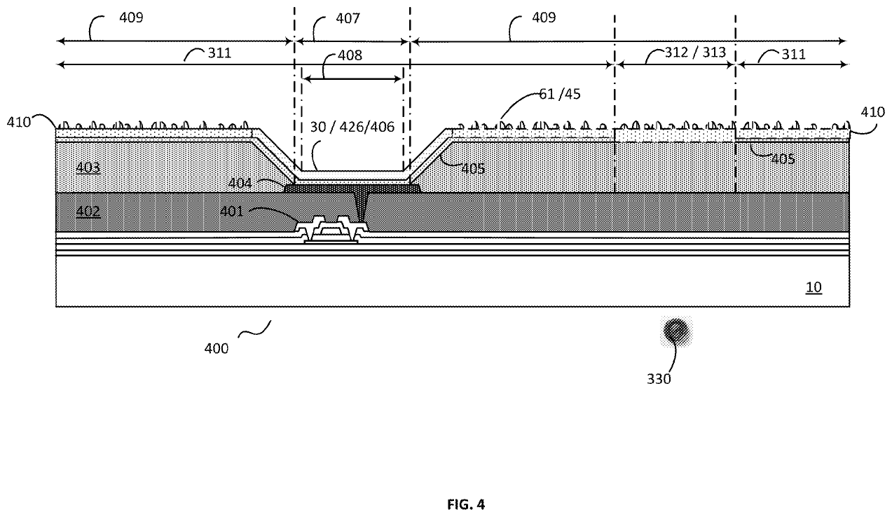

Turning now to FIG. 3A, there is a shown a cross-sectional view of an example layered device, such as a display panel 310. In some non-limiting examples, as shown in greater detail in FIG. 4, the display panel 310 may comprise a plurality of layers deposited upon a substrate 10, culminating with an outermost layer that forms a face 301 of the display panel 310.

A lateral axis, identified as the X-axis, is shown, together with a longitudinal axis, identified as the Z-axis. A second lateral axis, identified as the Y-axis, is shown as being substantially transverse to both the X-axis and the Z-axis. At least one of the lateral axes may define a lateral aspect of the display panel 310. The longitudinal axis may define a transverse aspect of the display panel 310.

The layers of the display panel 310 may extend in the lateral aspect substantially parallel to a plane defined by the lateral axes. Those having ordinary skill in the relevant art will appreciate that such substantially planar representation may be, in some non-limiting examples, an abstraction for purposes of illustration. In some non-limiting examples, there may be, across a lateral extent of the display panel 310, there may be localized substantially planar strata of different thicknesses and dimension, including, in some non-limiting examples, the substantially complete absence of a layer, and/or layer(s) separated by non-planar transition regions (including lateral gaps and even discontinuities).

Thus, while for illustrative purposes, the display panel 310 is shown in its cross-sectional aspect as a substantially stratified structure of substantially parallel planar layers, such display panel may illustrate locally, a diverse topography to define features, each of which may substantially exhibit the stratified profile discussed in the cross-sectional aspect.

The face 301 of the display panel 310 extends across the lateral aspect thereof, substantially along a plane defined by the lateral axes.

The lateral aspect of the display panel 310 may be understood to comprise at least one first portion 311 and at least one second portion 312. Each at least one second portion 312 corresponds to a blind hole region 313.

In some non-limiting examples, the display panel 310 may act as a face 301 of a user device 400 that houses at least one under-display component 330 therewithin, for exchanging the at least one EM signal 331 through the face 301 at an angle relative to the layers of the face 301.

In some non-limiting examples, there may be at least one blind hole region 313 on the display panel 310. As shown in the various examples in the figure, in some non-limiting examples, the at least one blind hole region 313 may be situated proximate to an edge of the display panel 310.

Turning now to FIG. 3B, there is shown a schematic diagram showing example faces of example user devices 300. In the plan view of FIG. 3B, a pair of lateral axes, identified as the X-axis and Y-axis respectively, which in some non-limiting examples may be substantially transverse to one another, are shown.

On at least one of such faces 300 of such user device 400, there is a display, which may, in some non-limiting examples, be the display panel 310 of FIG. 3A. On at least one of such faces 300, there may be at least one blind hole region 313. As shown in the various examples in the figure, in some non-limiting examples, the at least one blind hole region 313 may be situated to an edge of the face 301.

In some non-limiting examples, as shown in the first two examples in the figure, the blind hole region 313ₐ, 313_{b} may be substantially circular when viewed in plan, corresponding to a substantially circular cylindrical blind hole region 313 in cross-section. In some non-limiting examples, as shown in the third example in the figure, the blind hole region 313_{c} may have a different configuration, including without limitation, an elongate elliptical configuration when viewed in plan.

In some non-limiting examples, a cross-sectional dimension of the blind hole region 313 may be on the order of several mm, corresponding to a size in cross-section of an active sensor and/or emitter region of an associated under-display component 330.

In some non-limiting examples, the user device 400 may be a computing device, such as, without limitation, a smartphone, a tablet, a laptop, and/or an e-reader, and/or some other electronic device, such as a monitor, a television set, and/or a smart device, including without limitation, an automotive display and/or windshield, a household appliance, and/or a medical, commercial, and/or industrial device.

In some non-limiting examples, the face 301 may correspond to and/or mate with a body 320, and/or an opening 321 therewithin, within which the at least one under-display component 330 may be housed.

In some non-limiting examples, the at least one under-display component 330 may be formed integrally, or as an assembled module, with the display panel 310 on a surface thereof opposite to the face 301. In some non-limiting examples, the at least one under-display component 330 may be formed on a surface of the substrate 10 of the display panel 310 opposite to the face 301.

The blind hole region 313 defined by the at least one second portion 312 of the display panel 310 allows for the exchange of at least one EM signal 331 through the face 301 of the display panel 310, at an angle to the plane defined by the lateral axes, or concomitantly, the layers of the display panel 310, including without limitation, the face 301 of the display panel 310.

In other words, the at least one EM signal 331 passes through the blind hole region 313 of the second portion 312, such that it passes through the face 301. As a result, the at least one EM signal 331 excludes any EM radiation that may extend along the lateral aspect from the second portion 312 to the first portion 311 (or vice versa), including without limitation, any electric current that is conducted along a conductive coating laterally across the display panel 310.

Further, those having ordinary skill in the relevant art will appreciate that the at least one EM signal 331 may be differentiated from EM radiation per se, including without limitation electric current and/or an electrical field generated thereby, in that the at least one EM signal 331 conveys, either alone, or in conjunction with other EM signals 331, some information content, including without limitation, an identifier by which the at least one EM signal 331 may be distinguished from other EM signals 331. In some non-limiting examples, the information content may be conveyed by specifying, altering and/or modulating at least one of the wavelength, frequency, phase, timing, bandwidth, resistance, capacitance, impedance, conductance, and/or other characteristic of the at least one EM signal 331.

In some non-limiting examples, the at least one EM signal 331 passing through the blind hole region 313 of the second portion 312 of the display panel 310 may comprise at least one photon and, in some non-limiting examples, may have a wavelength spectrum that lies, without limitation, within the visible spectrum, the IR spectrum, and/or the NIR spectrum.

In some non-limiting examples, the photons passing through the blind hole region 313 of the second portion 312 of the display panel 310 may comprise ambient light incident thereon.

In some non-limiting examples, the at least one EM signal 331 exchanged through the blind hole region 313 of the second portion 312 of the display panel 310 may be transmitted and/or received by the at least one under-display component 331.

In some non-limiting examples, as shown by way of non-limiting example in FIG. 3C, the at least one under-display component 330 may comprise a receiver 330ᵣ adapted to receive and process at least one EM signal 331, including without limitation photons 331ᵣ, 332ᵣ, 333ᵣ, 334ᵣ, passing through the blind hole region 313 of the second portion 312 of the display panel 310 from beyond the user device 400. Non-limiting examples of such receiver 330ᵣ include an under-display camera (UDC) and/or a sensor, including without limitation, an IR sensor, an NIR sensor, a LIDAR sensor, a fingerprint sensor, an optical sensor, an infrared proximity sensor, an iris recognition sensor, and/or a facial recognition sensor.

In some non-limiting examples, as shown by way of non-limiting example in FIG. 3C, the at least one under-display component 330 may comprise a transmitter 330ₜ adapted to emit at least one EM signal 331, including without limitation, photons 331ₜ, 332ₜ passing through the blind hole region 313 of the second portion 312 of the display panel 310 beyond the user device 400. Non-limiting examples of such transmitter 330ₜ include a light source, including without limitation, a built-in flash, a flashlight, an IR emitter, and/or an NIR emitter, and/or a LIDAR sensing module, a fingerprint sensing module, an optical sensor, an IR sensor, an iris recognition module, and/or a facial recognition module.

In some non-limiting examples, as shown by way of non-limiting example in FIG. 3C, the at least one EM signal 331, including without limitation, photons 331ᵣ, 332ᵣ, 333ₑ, 334ₑ, passing through the blind hole region 313 of the second portion 312 of the display panel 310 beyond the user device 400, including without limitation, those emitted by at least one under-display component 330 that comprises a transmitter 330ₜ, may emanate from the display panel 310 and may be reflected off a surface 340 external to the user device 400 and pass back through the blind hole region 313 of the second portion 312 of the display panel 310 to at least one under-display component 330 that comprises a receiver 330ᵣ.

In some non-limiting examples, as shown by way of non-limiting example in FIG. 3C, there may be a plurality of under-display components 330 within the user device 400, a first one of which comprises a transmitter 330ₜ for emitting at least one EM signal 331, including without limitation, photons, to pass through the blind hole region 313 of the second portion 312 of the display panel 310, beyond the user device 400, and a second one of which comprises a receiver 330ᵣ, for receiving at least one EM signal 331, including without limitation, photons.

Although not shown, in some non-limiting examples, such transmitter 330ₜ and receiver 330ᵣ may be embodied in a single, common one of the at least one under-display components 330.

In some non-limiting examples, as shown by way of non-limiting example in FIG. 3C, the at least one under-display component 530 may not emit EM signals 331, including without limitation, photons, but rather the display panel 310 that forms the face 301 may comprise an opto-electronic device, including without limitation, an opto-luminescent device, including without limitation, an organic light-emitting diode (OLED) device, that emits photons 333ₑ, 334ₑ.

In some non-limiting examples, the emitted photons 333ₑ, 334ₑ, may be emitted, by the first portion 311 of the lateral aspect thereof, at an angle to the layers of the display panel 310, including without limitation, in a substantially longitudinal aspect.

In some non-limiting examples, the emitted photons 333ₑ, 334ₑ may be reflected off the surface 340 and returned through the display panel 310 to be received by the at least one under-display component 330ᵣ.

Turning now to FIG. 4, there is shown a simplified block diagram from a cross-sectional aspect, of a part of an example opto-electronic device 400, according to the present disclosure. The part of the device 400 shown will be understood to correspond largely to (a part of) one of the at least one first portions 311 and (a part of) one of the at least one second portions 312, of the display panel 310.

The device 400 may comprise a substrate 10, upon which a frontplane comprising a plurality of layers, including respectively a first electrode 404, at least one semiconducting layer 405, and a second electrode 406, may be disposed to provide mechanisms for photon emission and/or manipulation of emitted photons when coupled to a power source, at least in in the first portion 311.

In some non-limiting examples, the substrate 10 may be formed of material suitable for use therefor, including without limitation, an inorganic material, including without limitation, glass, sapphire, and/or other suitable inorganic material and/or an organic material, including without limitation, a polymer, including without limitation, a polyimide and an Si-based polymer.

In some non-limiting examples, additional layers that may, in some non-limiting examples, comprise and/or be formed of and/or as a backplane layer may be provided between the substrate 10 and the first electrode 404. In some non-limiting examples, the backplane layer may contain power circuitry and/or switching elements for driving the device 400, including without limitation, one or more electronic and/or opto-electronic components, including without limitation, thin-film transistor (TFT) transistors, resistors, and/or capacitors (collectively TFT structure 401), that, in some non-limiting examples, may be formed by a photolithography process. In some non-limiting examples, such TFT structures 401 may comprise a semiconductor active area formed over a part of a buffer layer, with a gate insulating layer deposited thereon to substantially cover it. In some non-limiting examples, a gate electrode may be formed on top of the gate insulating layer and an interlayer insulating layer may be deposited thereon.

In some non-limiting examples, there may be at least one emissive region 407 of the device 400 within the first portion 311 of the lateral aspect of the display panel 310. In some non-limiting examples, there may be a plurality of emissive regions 407 within the first portion 311.

By contrast, the second portion 312 is substantially devoid of any emissive regions 407, so as to provide the blind hole region 313 through which the at least one EM signal 331 may be exchanged.

Each emissive region 407 comprises a first electrode 404 and a second electrode 406. At least one semiconducting layer 405 lies between the first electrode 404 and the second electrode 406.

In some non-limiting examples, the first electrode 404 and/or the second electrode 406 may correspond respectively to an anode and a cathode, or vice versa. In some non-limiting examples, the first electrode 404 and/or the second electrode 406 may be electrically coupled to a terminal of the power source and/or to ground, in some non-limiting examples, through at least one driving circuit, which in some non-limiting examples, may incorporate at least one TFT structure 401 in the backplane layer. In some non-limiting examples, the first electrode 404 may comprise an anode. In some non-limiting examples, the second electrode 406 may comprise a cathode.

In some non-limiting examples, each emissive region 407 of the device 400 corresponds to a single display pixel 408ₚ. In some non-limiting examples, each pixel 408ₚ may emit light at a given wavelength spectrum. In some non-limiting examples, the wavelength spectrum may correspond to a colour in, without limitation, the visible spectrum.

In some non-limiting examples, each emissive region 407 of the device 400 may correspond to a sub-pixel 408ₛ of a display pixel 408ₚ. In some non-limiting examples, a plurality of sub-pixels 408ₛ may combine to form, or to represent, a single display pixel 408ₚ. In some non-limiting examples, a single display pixel 408ₚ may be represented by three or more sub-pixels 408ₛ, which in some non-limiting examples, may correspond to R(ed), G(reen), and/or B(lue) sub-pixels 408₃.

In some non-limiting examples, the emission spectrum of the light emitted by a given sub-pixel 408ₛ may correspond to the colour by which the sub-pixel 408ₛ is denoted.

In some non-limiting examples, individual emissive regions 407 of the device 400 may be laid out in a lateral pattern in the first portion 311. In some non-limiting examples, the pattern may extend along a first lateral direction, which in some non-limiting examples, may extend along a first lateral axis. In some non-limiting examples, the pattern may also extend along a second lateral direction, which in some non-limiting examples, may extend along a second lateral axis.

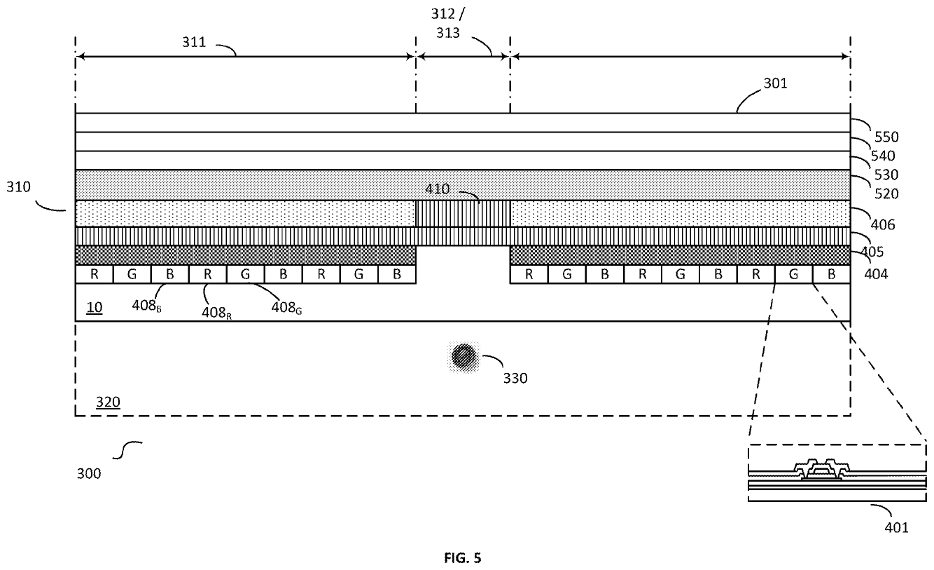

A non-limiting example of such a pattern is shown schematically in FIG. 5. However, for simplicity of illustration, rather than showing each of the emissive regions 407 corresponding to the sub-pixels 408ₛ, the pattern of the sub-pixels 408ₛ is represented by the corresponding TFT structures 401, each labelled with the associated sub-pixel 408ₛ corresponding to R(ed) 408_{R}, G(reen) 408_{G} and B(lue) 408_{B} sub-pixels.

With reference once again to FIG. 4, in some non-limiting examples, the at least one semiconducting layer 405 may comprise a plurality of layers, including without limitation, any one or more of a hole injection layer (HIL), a hole transport layer (HTL), an emissive layer (EML), an electron transport layer (ETL), and/or an electron injection layer (EIL).

When a potential difference is applied across the at least one semiconducting layer 405 through the first electrode 404 and the second electrode 406, holes may be injected through the anode and electrons may be injected through the cathode into the at least one semiconducting layer 405 until they may combine to form a bound state electron-hole pair (exciton). Especially if the exciton is formed in the EML, the exciton may decay through a radiative recombination process, in which a photon is emitted.

In some non-limiting examples, the various emissive regions 407 of the device 400 may be substantially surrounded and separated by, in at least one lateral direction, one or more non-emissive regions 409, in which the structure and/or configuration along the longitudinal aspect, of the device 400, may be varied, including without limitation, removing at least one of the first electrode 404, the second electrode 406, and/or the at least one semiconducting layer 405 therebetween, so as to substantially inhibit photons from being emitted therefrom

In some non-limiting examples, the non-emissive regions 409 may comprise those regions in the lateral aspect, that are substantially devoid of an emissive region 407. In some non-limiting examples, at least a part of at least one non-emissive region 409 may correspond to the second portion 312 of the lateral aspect.

In some non-limiting examples, a TFT source electrode and a TFT drain electrode, for an associated (sub-)pixel 408, may be formed, such that they extend through openings formed through both the interlayer insulating layer and the gate insulating layer such that they are electrically coupled to the semiconductor active area, in some non-limiting examples, substantially within the lateral aspect of the emissive region 407 corresponding thereto, that is, in the first portion 311. In some non-limiting examples, a TFT insulating layer 402 may then be formed over the TFT structure 401.

Thus, in some non-limiting examples, the first electrode 404 may be disposed over an exposed layer surface 11 of the device 400, in some non-limiting examples, within at least a part of the lateral aspect of the emissive region 407, that is, in the first portion 311.

In some non-limiting examples, at least within the lateral aspect of the emissive region 407 of the (sub-)pixel 408, the exposed layer surface 11 may comprise the TFT insulating layer 402 of the various TFT structures 401 that make up the driving circuit for the emissive region 407 corresponding to a single display (sub-)pixel 408. In some non-limiting examples, the first electrode 404 may extend through the TFT insulating layer 402 to be electrically coupled through the at least one driving circuit incorporating the at least one TFT structure 401 to a terminal of the power source and/or to ground.

In the longitudinal aspect, the configuration of each emissive region 407 may, in some non-limiting examples, be defined by the introduction of at least one pixel definition layer (PDL) 403 substantially throughout at least part of the lateral aspect of the surrounding non-emissive region(s) 409. In some non-limiting examples, the cross-sectional thickness and/or profile of the PDLs 403 may impart a substantially valley-shaped configuration to the emissive region 407 of each (sub-)pixel 408, by a region of increased thickness along a boundary, of the lateral aspect of the surrounding non-emissive region 409 with the lateral aspect of the surrounded emissive region 407.

In some non-limiting examples, in at least a part of the lateral aspect of such emissive region 407, the at least one semiconducting layer 405 may be deposited over the exposed layer surface 11 of the device 400, which may, in some non-limiting examples, comprise the first electrode 404, at least within the first portion 311.

The at least one semiconducting layer 405 may be deposited over the first electrode 404, in at least the lateral aspect of the emissive region 407 corresponding thereto.

The blind hole region 313 is formed in the second portion 312 by making the second portion(s) 312 substantially transmissive for EM signals 331 passing therethrough and through the face 301 at an angle to the layers of the display panel 310. In some non-limiting examples, such second portion(s) 312 may correspond to at least a part of at least one non-emissive region 409.

Although not shown, in some non-limiting examples, a thickness of the PDLs 403 in the second portion(s) 312, in some non-limiting examples, at least in a region laterally spaced apart from neighbouring emissive region(s) 407 in the first portion(s) 311, and in some non-limiting examples, of the TFT insulating layer 402, may be reduced, in order to enhance transmittivity therethrough.

As shown, the lateral aspect of the at least one blind hole region 313 is substantially devoid of any TFT structures 401.

In some non-limiting examples, one or more of the at least one semiconducting layers 405 may be selectively omitted within the at least one blind hole region 313 of the second portion 312, so as to reduce potential for interference with transmissivity of EM signals 331 therethrough, including without limitation, using a shadow mask.

### Nucleation-Inhibiting Coating (NIC)

In some non-limiting examples, a nucleation-inhibiting coating (NIC) 410 is formed on the exposed layer surface 11 in the second portion 312. In some non-limiting examples, the NIC is formed as a closed coating.

Whether or not a shadow mask is employed, the NIC 410 is restricted in its lateral aspect, substantially to the non-emissive region(s) 409, including without limitation, to the entirety of the second portion 312.

In some non-limiting examples, the NIC 410 and/or the NIC material 416 may be substantially transmissive.

While the NIC 410 extends across the entirety of the second portion 312, in some non-limiting examples, the NIC material 416 may be selectively deposited across parts of the first portion 311, including without limitation, using a shadow mask, to define features within the first portion 311, including without limitation, to define one or more non-emissive regions 409 surrounding an emissive region 407. In some non-limiting examples, the lateral extent of the emissive region 407 will be substantially devoid of the NIC material 416. In some non-limiting examples, at least a part of the lateral extent of the non-emissive region may have the NIC material 416 selectively deposited thereon.

In some non-limiting examples, the NIC 410 may provide a surface with a relatively low initial sticking probability S₀ against the deposition of a deposited material 426, which in some non-limiting examples, may be substantially less than the initial sticking probability S₀ (against the deposition of the deposited material 426) of the exposed layer surface 11 of underlying layer of the device 400, upon which the NIC 410 has been deposited.

Because of the low initial sticking probability S₀ of the NIC 410, and/or the NIC material 416, in some non-limiting examples, when deposited as a film and/or coating in a form, and under circumstances similar to the deposition of the NIC 410 within the device 400, against the deposition of the deposited material 426, the NIC 410 may be substantially devoid of a closed coating of the deposited material 426.

In some non-limiting examples, the NIC 410, and/or the NIC material 416, in some non-limiting examples, when deposited as a film and/or coating in a form, and under circumstances similar to the deposition of the NIC 410 within the device 400, may have an initial sticking probability S₀ (in some non-limiting examples, under the conditions identified in the dual QCM technique described by Walker et al.) against the deposition of the deposited material 426, that is less than about: 0.9, 0.3, 0.2, 0.15, 0.1, 0.08, 0.05, 0.03, 0.02, 0.01, 0.008, 0.005, 0.003, 0.001, 0.0008, 0.0005, 0.0003 or 0.0001.

In some non-limiting examples, the NIC 410, and/or the NIC material 416, in some non-limiting examples, when deposited as a film and/or coating in a form, and under circumstances similar to the deposition of the NIC 410 within the device 400, may have an initial sticking probability S₀ (in some non-limiting examples, under the conditions identified in the dual QCM technique described by Walker et al.) against the deposition of Ag and/or Mg that is less than about: 0.9, 0.3, 0.2, 0.15, 0.1, 0.08, 0.05, 0.03, 0.02, 0.01, 0.008, 0.005, 0.003, 0.001, 0.0008, 0.0005, 0.0003, or 0.0001.

In some non-limiting examples, the NIC 410, and/or the NIC material 416, in some non-limiting examples, when deposited as a film and/or coating in a form, and under circumstances similar to the deposition of the NIC 410 within the device 400, may have an initial sticking probability S₀ (in some non-limiting examples, under the conditions identified in the dual QCM technique described by Walker et al.) against the deposition of a deposited material 426 of between about: 0.15-0.0001, 0.1-0.0003, 0.08-0.0005, 0.08-0.0008, 0.05-0.001, 0.03-0.0001, 0.03-0.0003, 0.03-0.0005, 0.03-0.0008, 0.03-0.001, 0.03-0.005, 0.03-0.008, 0.03-0.01, 0.02-0.0001, 0.02-0.0003, 0.02-0.0005, 0.02-0.0008, 0.02-0.001, 0.02-0.005, 0.02-0.008, 0.02-0.01, 0.01-0.0001, 0.01-0.0003, 0.01-0.0005, 0.01-0.0008, 0.01-0.001, 0.01-0.005, 0.01-0.008, 0.008-0.0001, about 0.008-0.0003, 0.008-0.0005, 0.008-0.0008, 0.008-0.001, 0.008-0.005, 0.005-0.0001, 0.005-0.0003, 0.005-0.0005, 0.005-0.0008, or 0.005-0.001. In some non-limiting examples, the deposited material 426 may be, or contain, Ag.

In some non-limiting examples, the NIC 410, and/or the NIC material 416, in some non-limiting examples, when deposited as a film and/or coating in a form, and under circumstances similar to the deposition of the NIC 410 within the device 400, may have an initial sticking probability S₀ (in some non-limiting examples, under the conditions identified in the dual QCM technique described by Walker et al.) that is less than a threshold value against the deposition of a plurality of deposited materials 426. In some non-limiting examples, the threshold value may be about: 0.3, 0.2, 0.18, 0.15, 0.13, 0.1, 0.08, 0.05, 0.03, 0.02, 0.01, 0.08, 0.005, 0.003, or 0.001.

In some non-limiting examples, the NIC 410, and/or the NIC material 416, in some non-limiting examples, when deposited as a film and/or coating in a form, and under circumstances similar to the deposition of the NIC 410 within the device 400, may have an initial sticking probability S₀ (in some non-limiting examples, under the conditions identified in the dual QCM technique described by Walker et al.) that is less than a threshold value against the deposition of two or more deposited materials 426 selected from: Ag, Mg, Yb, Cd, and Zn. In some further non-limiting examples, the NIC 410 may exhibit S₀ of or below a threshold value for two or more deposited materials 426 selected from: Ag, Mg, and Yb.

In some non-limiting examples, the NIC 410, and/or the NIC material 416, in some non-limiting examples, when deposited as a film and/or coating in a form, and under circumstances similar to the deposition of the NIC 410 within the device 400, may exhibit an initial sticking probability S₀ of or below a first threshold value against the deposition of a first deposited material 426, and an initial sticking probability S₀ of or below a second threshold value against the deposition of a second deposited material 426. In some non-limiting examples, the first deposited material 426 may be Ag and the second deposited material 426 may be Mg. In some other non-limiting examples, the first deposited material 426 may be Ag and the second deposited material 426 may be Yb. In some other non-limiting examples, the first deposited material 426 may be Yb and the second deposited material 426 may be Mg. In some non-limiting examples, the first threshold value may be greater than the second threshold value.

In some non-limiting examples, the NIC 410, and/or the NIC material 416, in some non-limiting examples, when deposited as a film and/or coating in a form, and under circumstances similar to the deposition of the NIC 410 within the device 400, may have a (light) transmittance of or above a threshold transmittance value after being subjected to a vapor flux of Ag.

In some non-limiting examples, the transmittance may be measured after exposing the surface of the NIC 410 and/or the NIC material 416, formed as a thin film, to a vapor flux of Ag under typical conditions used for depositing an electrode of an opto-electronic device, which by way of non-limiting example may be a cathode of an OLED device.

In some non-limiting examples, the conditions for subjecting the surface to the vapor flux of Ag may be as follows: (i) vacuum pressure of about 10⁻⁴ Torr or 10⁻⁵ Torr; (ii) the vapor flux of Ag being substantially consistent with a reference deposition rate of about 1 angstrom (A)/sec, which by way of non-limiting example may be monitored or measured using a QCM; and (iii) the surface being subjected to the vapor flux of Ag until a reference thickness of 15 nm is reached, and upon such reference thickness being attained, the surface not being further subjected to the vapor flux of Ag.

In some non-limiting examples, the surface being subjected to the vapor flux of Ag may be substantially at room temperature (e.g. about 25° C.). In some non-limiting examples, the surface being subjected to the vapor flux of Ag may be positioned about 65 cm away from the evaporation source from which Ag is evaporated.

In some non-limiting examples, the threshold transmittance value may be measured at a wavelength corresponding to the visible spectrum. By way of non-limiting example, the threshold transmittance value may be measured at a wavelength of about 460 nm. In some non-limiting examples, the threshold transmittance value may be expressed as a percentage of the incident electromagnetic power that is transmitted through a sample. In some non-limiting examples, the threshold transmittance value may be at least: about 60%, about 65%, about 70%, about 75%, about 80%, about 85%, or about 90%.

In some non-limiting examples, there may be a positive correlation between the initial sticking probability S₀ of the NIC 410, and/or the NIC material 416, in some non-limiting examples, when deposited as a film and/or coating in a form, and under circumstances similar to the deposition of the NIC 410 within the device 400, against the deposition of the deposited material 426 and a thickness of the deposited material 426 thereon.

It would be appreciated by a person having ordinary skill in the relevant art that high transmittance may generally indicate absence of a closed coating of the deposited material 426, which by way of non-limiting example may be Ag. On the other hand, low transmittance may generally indicate presence of a closed coating of the deposited material 426, including without limitation, Ag, Mg, and/or Yb, since metallic thin films, particularly when formed as a closed coating, may exhibit high degree of light absorption.

It is further postulated that surfaces exhibiting low initial sticking probability S₀ with respect to the deposited material 426, including without limitation, Ag, Mg, and/or Yb, may exhibit high transmittance. On the other hand, surfaces exhibiting high sticking probability S₀ with respect to the deposited material 426, including without limitation, Ag, Mg, and/or Yb, may exhibit low transmittance.

A series of samples was fabricated to measure the transmittance, as well as to visually observe whether or not a closed coating of Ag was formed. Each sample was prepared by depositing, on a glass substrate, an approximately 50 nm thick coating of a material, then subjecting the surface of the coating to a vapor flux of Ag at a rate of about 1 Å/sec until a reference layer thickness of 15 nm was reached. Each sample was then visually analyzed and the transmittance through each sample was measured.

The molecular structures of the materials used in some non-limiting examples herein are set out below.

| Material | Molecular Structure/Name |
|---|---|
| HT211 | 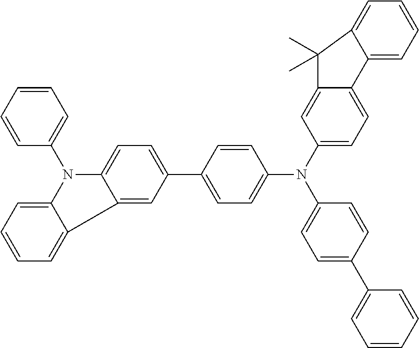 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21] |
| HT01 | 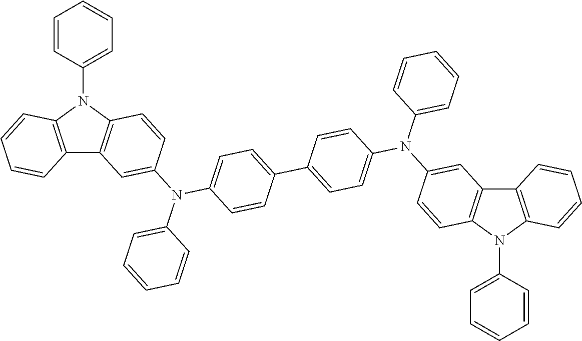 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1] |
| TAZ | 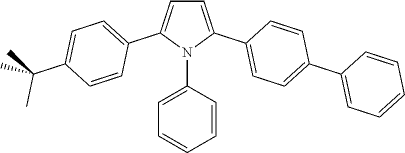 |
| BAlq | 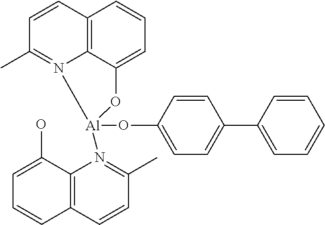 |
| Liq | 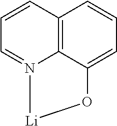 |
| Example Material 1 | 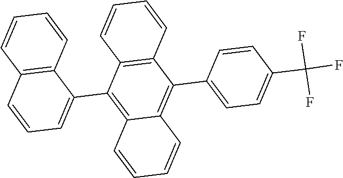 [SMILES: FC(F)(F)c1ccc(-c2c3ccccc3c(-c3cccc4ccccc34)c3ccccc23)cc1] |
| Example Material 2 | 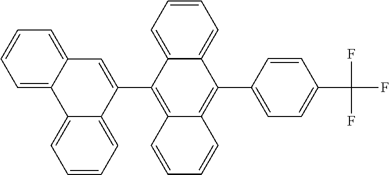 [SMILES: FC(F)(F)c1ccc(-c2c3ccccc3c(-c3cc4ccccc4c4ccccc34)c3ccccc23)cc1] |
| Example Material 3 | 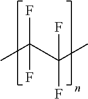 |
| Example Material 4 | 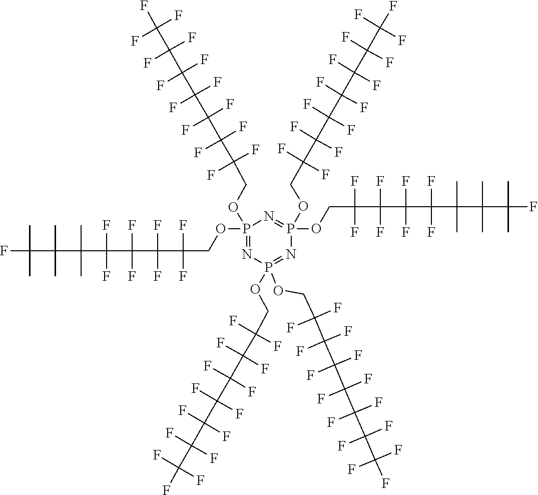 [SMILES: CC(C)(F)C(C)(C)C(C)(C)C(F)(F)C(F)(F)C(F)(F)C(F)(F)COP1(OCC(F)(F)C(F)(F)C(F)(F)C(F)(F)C(F)(F)C(F)(F)C(F)(F)F)=NP(OCC(F)(F)C(F)(F)C(F)(F)C(F)(F)C(C)(C)C(C)(C)C(C)(C)F)(OCC(F)(F)C(F)(F)C(F)(F)C(F)(F)C(F)(F)C(F)(F)C(F)(F)F)=NP(OCC(F)(F)C(F)(F)C(F)(F)C(F)(F)C(F)(F)C(F)(F)C(F)(F)F)(OCC(F)(F)C(F)(F)C(F)(F)C(F)(F)C(F)(F)C(F)(F)C(F)(F)F)=N1] |
| Example Material 5 | 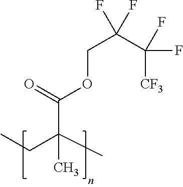 |
| Example Material 6 | 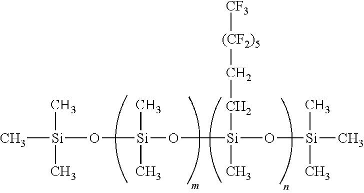 |
| Example Material 7 | 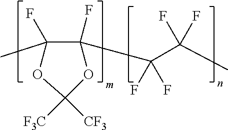 |
| Example Material 8 | 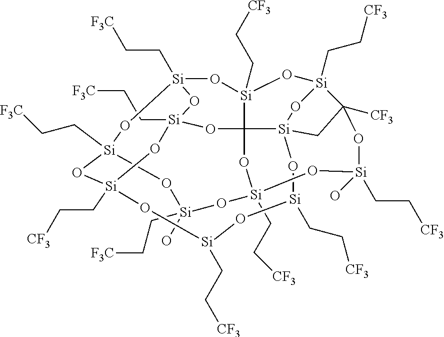 |
| Example Material 9 | 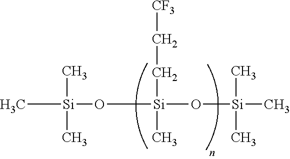 |

The samples in which a substantially closed coating of Ag had formed were visually identified, and the presence of such coating in these samples was further confirmed by measurement of transmittance, which showed transmittance of no more than 50% at a wavelength of 460 nm.

The samples in which no closed coating of Ag had formed were also visually identified, and the absence of such coating in these samples was further confirmed by measurement of transmittance, which showed transmittance in excess of 70% at a wavelength of 460 nm.

The results are summarized in the table below.

| Material | Closed Coating of Ag? |
|---|---|
| HT211 | Present |
| HT01 | Present |
| TAZ | Present |
| Balq | Present |
| Liq | Present |
| Example Material 1 | Present |
| Example Material 2 | Present |
| Example Material 3 | Not Present |
| Example Material 4 | Not Present |
| Example Material 5 | Not Present |
| Example Material 6 | Not Present |
| Example Material 7 | Not Present |
| Example Material 8 | Not Present |
| Example Material 9 | Not Present |

Based on the foregoing, it was found that the materials used in the first 7 samples in the table (HT211 to Example Material 2) may not be particularly suitable for inhibiting the deposition of the deposited material 426 thereon, including without limitation, Ag and/or Ag-containing materials.

On the other hand, it was found that Example Material 3 to Example Material 9 may be suitable, in at least some applications, as the NIC 410 for inhibiting the deposition of the deposited material 426 thereon, including without limitation, Ag and/or Ag-containing materials.

In some non-limiting examples, the NIC 410, and/or the NIC material 416, in some non-limiting examples, when deposited as a film and/or coating in a form, and under circumstances similar to the deposition of the NIC 410 within the device 400, may have a surface energy Y1 of less than about: 24 dynes/cm, 22 dynes/cm, 20 dynes/cm, 18 dynes/cm, 16 dynes/cm, 15 dynes/cm, 13 dynes/cm, 12 dynes/cm, or 11 dynes/cm. In some non-limiting examples, the surface energy Y1 may exceed about: 6 dynes/cm, 7 dynes/cm, or 8 dynes/cm. In some non-limiting examples, the surface energy Y1 may be between about: 10-20 dynes/cm, or 13-19 dynes/cm. In some non-limiting examples, the critical surface tension of a surface may be determined according to the Zisman method, as further detailed in W. A. Zisman, Advances in Chemistry 43 (1964), P. 1-51.

By way of non-limiting example, a series of samples was fabricated to measure the critical surface tension of the surfaces formed by the various materials. The results of the measurement are summarized below.

| | Critical Surface Tension |
|---|---|
| Material | (dynes/cm) |
| HT211 | 25.6 |
| HT01 | >24 |
| TAZ | 22.4 |
| BAlq | 25.9 |
| Liq | 24 |
| Example Material 1 | 26.3 |
| Example Material 2 | 24.8 |
| Example Material 3 | 19 |
| Example Material 4 | 7.6 |
| Example Material 5 | 15.9 |
| Example Material 6 | <20 |
| Example Material 7 | 13.1 |
| Example Material 8 | 20 |
| Example Material 9 | 18.9 |

Based on the foregoing measurement of the critical surface tension and the previous observation regarding the presence or absence of a substantially closed coating of Ag, it was found that materials that form low surface energy surfaces when deposited as a coating, which by way of non-limiting example, may be those having a critical surface tension of between about: 13-20 dynes/cm, or 13-19 dynes/cm, may be particularly useful for forming the NIC 410 to inhibit deposition of a deposited material 426 thereon, including without limitation, Ag and/or Ag-containing materials.

Without wishing to be bound by any particular theory, it may be postulated that materials that form surfaces having a surface energy lower than, by way of non-limiting example, about 13 dynes/cm, may not be well suited as an NIC material 410 in certain applications, as such materials may exhibit poor adhesion to layer(s) surrounding such materials, exhibit a low melting point, and/or exhibit a low sublimation temperature.

In some non-limiting examples, the NIC 410, and/or the NIC material 416, in some non-limiting examples, when deposited as a film and/or coating in a form, and under circumstances similar to the deposition of the NIC 410 within the device 400, may have a low refractive index n. In some non-limiting examples, the NIC 410, and/or the NIC material 416, in some non-limiting examples, when deposited as a film and/or coating in a form, and under circumstances similar to the deposition of the NIC 410 within the device 400, may have a refractive index n for photons at a wavelength of 550 nm that may be less than about: 1.55, 1.5, 1.45, 1.43, 1.4, 1.39, 1.37, 1.35, 1.32, or 1.3. Without wishing to be bound by any particular theory, it has been observed that providing the NIC 410 having a low refractive index n may, at least in some devices 400, enhance transmission of external light through the second portion 312 thereof. By way of non-limiting example, devices 400 including an air gap therein, which may be arranged near or adjacent to the NIC 410, may exhibit higher transmittance when the NIC 410 has a low refractive index n compared to a similarly configured device 400 in which such low-index NIC 410 is not provided.

By way of non-limiting example, a series of samples was fabricated to measure the refractive index at a wavelength of 550 nm for the coatings formed by some of the various materials. The results of the measurement are summarized below.

| Material | Refractive Index |
|---|---|
| HT211 | 1.76 |
| HT01 | 1.80 |
| TAZ | 1.69 |
| BAlq | 1.69 |
| Liq | 1.64 |
| Example Material 2 | 1.72 |
| Example Material 3 | 1.37 |
| Example Material 5 | 1.38 |
| Example Material 7 | 1.3 |

Based on the foregoing measurement of refractive index n and the previous observation regarding the presence or absence of a substantially closed coating of Ag, it was found that materials that form a low refractive index n coating, which by way of non-limiting examples, may be those having a refractive index n of no more than 1.4 or 1.38, may be suitable for forming the NIC 410 to inhibit deposition of a deposited material 426 thereon, including without limitation, Ag and/or an Ag-containing materials.

In some non-limiting examples, the NIC 410 and/or the NIC material 416, in some non-limiting examples, when deposited as a film and/or coating in a form, and under circumstances similar to the deposition of the NIC 410 within the device 400, may have an extinction coefficient k that may be less than about 0.01 for photons at a wavelength that exceeds at least one of about: 600 nm, 500 nm, 460 nm, about 420 nm, or 410 nm. In some non-limiting examples, the NIC 410 and/or the NIC material 416, in some non-limiting examples, when deposited as a film and/or coating in a form, and under circumstances similar to the deposition of the NIC 410 within the device 400, may not substantially attenuate light passing therethrough in at least the visible spectrum. In some non-limiting examples, the NIC 410 and/or the NIC material 416, when deposited as a film and/or coating in a form, and under circumstances similar to the deposition of the NIC 410 within the device 400, may not substantially attenuate light passing therethrough in at least the IR spectrum and/or the NIR spectrum.

In some non-limiting examples, the NIC 410 and/or the NIC material 416, in some non-limiting examples, when deposited as a film and/or coating in a form, and under circumstances similar to the deposition of the NIC 410 within the device 400, may have an extinction coefficient k that may be greater than about: 0.05, 0.1, 0.2, or 0.5 for photons at a wavelength shorter than at least about: 400 nm, 390 nm, 380 nm, or 370 nm. In this way, the NIC 410 and/or the NIC material 416, when deposited as a film and/or coating in a form, and under circumstances similar to the deposition of the NIC 410 within the device 400, may absorb light in the UVA spectrum light incident upon the device, thereby reducing the likelihood of light in the UVA spectrum imparting undesirable effects in terms of device performance, device stability, device reliability, and/or device lifetime.

In some non-limiting examples, the NIC 410, and/or the NIC material 416, in some non-limiting examples, when deposited as a film and/or coating in a form, and under circumstances similar to the deposition of the NIC 410 within the device 400, may have a glass transition temperature T_{g} that is less than about: 300° C., 150° C., 130° C., 30° C., 0° C., −30° C., or −50° C.

In some non-limiting examples, the NIC material 416 may have a sublimation temperature of between about: 100-320° C., 120-300° C., 140-280° C., or 150-250° C. In some non-limiting examples, such sublimation temperature may allow the NIC material 416 to be readily deposited as a coating using physical vapor deposition (PVD).

The sublimation temperature of a material may be determined using various methods apparent to those having ordinary skill in the relevant art, including without limitation, by heating the material under high vacuum in a crucible and by determining a temperature that may be attained to:
observe commencement of the deposition of the material onto a surface on a QCM mounted a fixed distance from the crucible;
observe a specific deposition rate, by way of non-limiting example, 0.1 Å/sec, onto a surface on a QCM mounted a fixed distance from the crucible; and/or
reach a threshold vapor pressure of the material, by way of non-limiting example, about 10⁻⁴ or 10⁻⁵ Torr.

In some non-limiting examples, the sublimation temperature of a material may be determined by heating the material in an evaporation source under a high vacuum environment, by way of non-limiting example, about 10⁻⁴ Torr, and by determining a temperature that may be attained to cause the material to evaporate, thus generating a vapor flux sufficient to cause deposition of the material, by way of non-limiting example, at a deposition rate of about 0.1 Å/sec onto a surface on a QCM mounted a fixed distance from the source.

In some non-limiting examples, the QCM may be mounted about 65 cm away from the crucible for the purpose of determining the sublimation temperature.

In some non-limiting examples, the NIC 410 and/or the patterning material 316 may contain a fluorine (F) atom and/or a silicon (Si) atom. By way of non-limiting example, the NIC material 416 for forming the NIC 410 may be a compound that includes F and/or Si.

In some non-limiting examples, the NIC material 416 may be a compound that includes F. In some non-limiting examples, the NIC material 416 may be a compound that includes F and a carbon (C) atom. In some non-limiting examples, the NIC material 416 may be a compound that includes F and C in an atomic ratio corresponding to a quotient of F/C of at least about: 1, 1.5, or 2. In some non-limiting examples, the atomic ratio of F to C may be determined by counting all of the F atoms present in the compound structure, and for C atoms, counting solely the sp³ hybridized C atoms present in the compound structure. In some non-limiting examples, the NIC material 416 may be a compound that includes, as part of its molecular sub-structure, a moiety containing F and C in an atomic ratio corresponding to a quotient of F/C of at least about: 1, 1.5, or 2.

In some non-limiting examples, the NIC material 416 may be, or contain, an oligomer.

In some non-limiting examples, the NIC material 416 may be, or contain, a compound having a molecular structure containing a backbone and at least one functional group bonded to the backbone.

In some non-limiting examples, such compound may have a molecular structure containing a siloxane group. In some non-limiting examples, the siloxane group may be a linear, branched, or cyclic siloxane group. In some non-limiting examples, the backbone may be, or contain, a siloxane group. In some non-limiting examples, the backbone may be, or contain, a siloxane group and at least one functional group containing fluorine. In some non-limiting examples, the at least one functional group containing fluorine may be a fluoroalkyl group. Non-limiting examples of such compound include fluoro-siloxanes. Non-limiting examples of such compound are Example Material 6 and Example Material 9.

In some non-limiting examples, the compound may have a molecular structure containing a silsesquioxane group. In some non-limiting examples, the silsesquioxane group may be a polyhedral oligomeric silsesquioxane (POSS). In some non-limiting examples, the backbone may be, or contain, a silsesquioxane group. In some non-limiting examples, the backbone may be, or contain, a silsesquioxane group and at least one functional group containing fluorine. In some non-limiting examples, the at least one functional group containing fluorine may be a fluoroalkyl group. Non-limiting examples of such compound include fluoro-silsesquioxane and/or fluoro-POSS. A non-limiting example of such compound is Example Material 8.

In some non-limiting examples, the compound may have a molecular structure containing a substituted or unsubstituted aryl group, and/or a substituted or unsubstituted heteroaryl group. In some non-limiting examples, the aryl group may be phenyl, or naphthyl. In some non-limiting examples, one or more C atoms of an aryl group may be substituted by a heteroatom, which by way of non-limiting example may be oxygen (O), nitrogen (N), and/or sulfur (S), to derive a heteroaryl group. In some non-limiting examples, the backbone may be, or contain, a substituted or unsubstituted aryl group, and/or a substituted or unsubstituted heteroaryl group. In some non-limiting examples, the backbone may be, or contain, a substituted or unsubstituted aryl group, and/or a substituted or unsubstituted heteroaryl group and at least one functional group containing fluorine. In some non-limiting examples, the at least one functional group containing fluorine may be a fluoroalkyl group.

In some non-limiting examples, the compound may have a molecular structure containing a substituted or unsubstituted, linear, branched, or cyclic hydrocarbon group. In some non-limiting examples, one or more C atoms of the hydrocarbon group may be substituted by a heteroatom, which by way of non-limiting example may be O, N, and/or S.

In some non-limiting examples, the compound may have a molecular structure containing a phosphazene group. In some non-limiting examples, the phosphazene group may be a linear, branched, or cyclic phosphazene group. In some non-limiting examples, the backbone may be, or contain, a phosphazene group. In some non-limiting examples, the backbone may be, or contain, a phosphazene group and at least one functional group containing fluorine. In some non-limiting examples, the at least one functional group containing fluorine may be a fluoroalkyl group. Non-limiting examples of such compound include fluoro-phosphazenes. A non-limiting example of such compound is Example Material 4.

In some non-limiting examples, the compound may be a fluoropolymer. In some non-limiting examples, the compound may be a block copolymer containing F. In some non-limiting examples, the compound may be an oligomer. In some non-limiting examples, the oligomer may be a fluorooligomer. In some non-limiting examples, the compound may be a block oligomer containing F. Non-limiting examples, of fluoropolymers and/or fluorooligomers are those having the molecular structure of Example Material 3, Example Material 5, and/or Example Material 7.

In some non-limiting examples, the compound may be a metal complex. In some non-limiting examples, the metal complex may be an organo-metal complex. In some non-limiting examples, the organo-metal complex may contain F. In some non-limiting examples, the organo-metal complex may include at least one ligand containing F. In some non-limiting examples, the at least one ligand containing F may be, or contain, a fluoroalkyl group.

In some non-limiting examples, the NIC material 416 may be, or contain, an organic-inorganic hybrid material. Such material may generally include a portion or a moiety which is organic, and another portion or another moiety which is inorganic. Non-limiting examples of such material are those containing a siloxane group, a silsesquioxane group, a POSS group, a phosphazene group, and/or a metal complex.

In some non-limiting examples, the NIC material 416 may comprise a plurality of different materials.

In some non-limiting examples, the NIC material 416 may be doped, covered, and/or supplemented with another material that may act as a seed or as a defect and/or an anomaly on the exposed layer surface 11, including without limitation, a ledge, a step edge, a chemical impurity, a bonding site, and/or a kink (“heterogeneity”), to act as a nucleation site for the deposited material 426. In some non-limiting examples, such other material may comprise a nucleation-promoting coating (NPC) material. In some non-limiting examples, such other material may comprise an organic material, such as by way of non-limiting example, a polycyclic aromatic compound, and/or a material containing a non-metallic element such as, without limitation, O, S, N, or C, whose presence might otherwise be considered to be a contaminant in the source material, equipment used for deposition, and/or the vacuum chamber environment. In some non-limiting examples, such other material may be deposited in a layer thickness that is a fraction of a monolayer, so as to avoid forming a continuous coating 30 thereof. Rather, the monomers of such other material will tend to be spaced apart in the lateral aspect so as to form discrete nucleation sites for the deposited material 426.

In some non-limiting examples, the NIC 410 may be disposed in a pattern that may be defined by at least one region therein that is substantially devoid of a closed coating of the NIC coating. In some non-limiting examples, the at least one region may separate the NIC 410 into a plurality of discrete fragments thereof. In some non-limiting examples, the plurality of discrete fragments of the NIC 410 may be physically spaced apart from one another in the lateral aspect thereof. In some non-limiting examples, the plurality of the discrete fragments of the NIC 410 may be arranged in a regular structure, including without limitation, an array or matrix, such that in some non-limiting examples, the discrete fragments of the NIC 410 are configured in a repeating pattern.

In some non-limiting examples, at least one of the plurality of the discrete fragments of the NIC 410 may each correspond to an emissive region 407. In some non-limiting examples, an aperture ratio of the emissive regions 407 may be no more than about: 50%, 40%, 30%, or 20%.

In some non-limiting examples, an average film thickness of the NIC 410 may be between about 1-100 nm. In some non-limiting examples, the average film thickness of the NIC 410 may be less than about: 80 nm, 60 nm, 50 nm, 40 nm, 30 nm, 20 nm, 15 nm, or 10 nm. In some non-limiting examples, the average film thickness of the patterning layer may exceed about: 3 nm, 5 nm, or 8 nm.

In some non-limiting examples, the average film thickness of the NIC 410 may be less than about 10 nm. Without wishing to be bound by any particular theory, it has been found, somewhat surprisingly, that an average film thickness of the NIC 410 that is greater than zero and less than about 10 nm may, at least in some non-limiting examples, provide certain advantages for achieving, by way of non-limiting example, enhanced patterning contrast of the deposited material 426, relative to a NIC 410 having an average film thickness in excess of 10 nm.

In some non-limiting examples, the NIC 410 may be formed as a single monolithic coating.

In some non-limiting examples, the NIC 410 may act as an optical coating. In some non-limiting examples, the NIC 410 may modify at least one property and/or characteristic of the light emitted from at least one emissive region 407 of the device 400. In some non-limiting examples, the NIC 410 may exhibit a degree of haze, causing emitted light to be scattered. In some non-limiting examples, the NIC 410 may comprise a crystalline material for causing light transmitted therethrough to be scattered. Such scattering of light may facilitate enhancement of the out-coupling of light from the device 400 in some non-limiting examples, In some non-limiting examples, the NIC 410 may initially be deposited as a substantially non-crystalline, including without limitation, substantially amorphous coating, whereupon, after deposition thereof, the NIC 410 may become crystallized and thereafter serve as an optical coupling.

In some non-limiting examples, the NIC 410 may be deposited specifically to act as such. In some non-limiting examples, the NIC 410 may be deposited as part of the manufacturing process but also serve as the NIC 410.

### Deposited Material

After selective deposition of the NIC 410 across at least the second portion 312, the exposed layer surface 11 of the device 400 may be exposed to a vapor flux of the deposited material 426, including without limitation, in an open mask and/or mask-free deposition process.

In some non-limiting examples, the exposed layer surface 11 of the device 400 within the lateral aspect of the non-emissive region(s) 409, including without limitation, the entirety of the second portion 312, may comprise the NIC 410. Accordingly, in such region(s), the deposited material 426 may tend not to form as a closed coating thereof.

In some non-limiting examples, such regions may be substantially devoid of a closed coating of the deposited material 426.

Thus, it may be seen that the at least one blind hole region 313 of the second portion 312 of the device 400 may be substantially devoid of any non-transmissive elements such as a TFT structure 401, associated conductive metal lines, the first electrode 404 or the second electrode 406.

### Particle Structure

Without wishing to be limited to any particular theory, it may be postulated that, while the formation of a closed coating of the deposited material 426 thereon may be substantially inhibited on a closed coating of the NIC 410, in some non-limiting examples, when the NIC 410 is exposed to deposition of the deposited material 426 thereon, some vapor monomers of the deposited material 426 may ultimately form at least one particle, including without limitation, a nanoparticle (NP), and/or network thereof (collectively particle structure 61), thereon.

Accordingly, the exposed layer surface 11 of the device 400 within the lateral aspect of the non-emissive region(s) 409, including without limitation, the entirety of the second portion 312, may comprise, in some non-limiting examples, an intermediate stage layer and/or a discontinuous coating. In the present disclosure, for purposes of simplicity of description, the term “discontinuous layer” will be understood to encompass either or both of an intermediate stage layer and a discontinuous coating.

Thus, such regions may comprise a discontinuous layer that comprises at least one particle structure 61 of the deposited material 426. In some non-limiting examples, at least some of the particle structures 61 may be disconnected from one another. In other words, in some non-limiting examples, the discontinuous layer may comprise features, including particle structures 61, that are physically separated from one another, such that a closed coating is not formed thereon.

Such regions may, in some non-limiting examples, thus comprise a thin disperse layer of deposited material 426 formed as particle structures 61.

In some non-limiting examples, at least one of the particle structures 61 of deposited material 426 may be in physical contact with an exposed layer surface 11 of the NIC 410. In some non-limiting examples, substantially all of the particle structures 61 of deposited material 426 may be in physical contact with the exposed layer surface 11 of the NIC 410.

Without wishing to be bound by any particular theory, it has been found, somewhat surprisingly, that the presence of such a thin, disperse layer of deposited material 426, including without limitation, at least one particle structure 61, including without limitation, metal particle structures 61, including without limitation, in a discontinuous layer, at and/or proximate to an exposed layer surface 11 of the NIC 410, including without limitation, at an interface with a covering layer thereon, may exhibit one or more varied characteristics and concomitantly, varied behaviours, including without limitation, optical effects and properties of the device 400 on photons and/or EM signals emitted by the device 400, and/or exchanged through the second portion 312 of the face 301, as discussed herein. In some non-limiting examples, such effects and properties may be controlled to some extent by judicious selection of a characteristic size, size distribution, shape, coverage, configuration, deposited density, and/or dispersity of such particle structures 61 on the NIC 410.

In some non-limiting examples, the formation of at least one of the characteristic size, size distribution, shape, coverage, configuration, deposited density, and/or dispersity of particle structures 61 on the NIC 410, may be controlled, in some non-limiting examples, by judicious selection of at least one of: at least one of a characteristic of the NIC material 416, the average film thickness of the NIC 410, the introduction of heterogeneities in the NIC 410, and/or a deposition environment, including without limitation, a temperature, pressure, duration, deposition rate, and/or method of deposition for the NIC 410.

In some non-limiting examples, the formation of the characteristic size, size distribution, shape, coverage, configuration, deposited density, and/or dispersity of such particle structures 61 may be controlled, in some non-limiting examples, by judicious selection of at least one of: at least one characteristic of the deposited material 426, an extent to which the NIC 410 may be exposed to deposition of the deposited material 426 (which, in some non-limiting examples, may be specified in terms of a reference layer thickness of the deposited material 426, and/or a deposition environment, including without limitation, a temperature, pressure, duration, deposition rate, and/or method of deposition for the particle structures 61.

Those having ordinary skill in the relevant art will appreciate that certain metal NPs may exhibit surface plasmon (SP) excitations and/or coherent oscillations of free electrons, with the result that such NPs may absorb and/or scatter light in a range of the EM spectrum, including without limitation, the visible spectrum and/or a sub-range thereof. The optical response, including without limitation, the (sub-)range of the EM spectrum over which absorption may be concentrated (absorption spectrum), refractive index n, and/or extinction coefficient k, of such localized SP (LSP) excitations and/or coherent oscillations, may be tailored by varying properties of such NPs, including without limitation, a characteristic size, size distribution, shape, coverage, configuration, deposition density, dispersity, and/or property, including without limitation, material, and/or degree of aggregation, of the nanostructures and/or a medium proximate thereto.

In some non-limiting examples, the presence of at least one particle structure 61 of deposited material 426 may contribute to enhanced light extraction, performance, stability, reliability, and/or lifetime of the device 400.

Those having ordinary skill in the relevant art will appreciate that, while a simplified model of the optical effects is presented herein, other models and/or explanations may be applicable.

In some non-limiting examples, the presence of at least one particle structure 61 of the deposited material 426, may reduce and/or mitigate crystallization of thin film layers and/or coatings disposed adjacent thereto in the longitudinal aspect, including without limitation, the NIC 410 and/or any covering layer, thereby stabilizing the property of the thin film(s) disposed adjacent thereto, and, in some non-limiting examples, reducing light scattering.

In some non-limiting examples, the presence of at least one particle structure 61 of deposited material, may provide an enhanced absorption in at least a part of the UV spectrum. In some non-limiting examples, controlling the characteristics of such particle structures 61, including without limitation, characteristic size, size distribution, shape, coverage, configuration, deposited density, dispersity, deposited material 426, and refractive index n, of the particle structures 61, may facilitate controlling the degree of absorption, wavelength range and peak wavelength λₘₐₓ of the absorption spectrum, including in the UV spectrum. Enhanced absorption of light in at least a part of the UV spectrum may be advantageous, for example, for improving device performance, stability, reliability, and/or lifetime. In some non-limiting examples, various characteristics of the particle structures 61 may be modulated by the properties of the surrounding media, coating, and/or layers. In some non-limiting examples, the particle structures 61 are disposed in contact with a NIC 410 and/or a low-index coating to modulate the absorption characteristics and/or refractive index n of the particle structures 61.

In some non-limiting examples, the optical effects may be described in terms of its impact on the transmission and/or absorption wavelength spectrum, including a wavelength range and/or peak intensity thereof.

Additionally, while the model presented may suggest certain effects imparted on the transmission and/or absorption of photons passing through such particle structures 61, in some non-limiting examples, such effects may reflect local effects that may not be reflected on a broad, observable basis.

Typically, the size of particle structures 61 in (an observation window of) the lateral aspect of the non-emissive region(s) 409, including without limitation, the entirety of the second portion 312, may reflect a statistical distribution.

In some non-limiting examples, absorption spectrum intensity may tend to be proportional to the deposited density of such regions, for a particular distribution of characteristic size S1 of particle structures 61.

The foregoing also assumes, as a simplifying assumption, that the NPs modelling each particle structure 61 may have a perfectly spherical shape. Typically, the shape of particle structures 61 in (an observation window of) such regions may be highly dependent upon the deposition process. In some non-limiting examples, the shape of the particle structures 61 may have a significant impact on the SP excitation exhibited thereby, including without limitation, on the width, wavelength range, and/or intensity of the resonance band, and concomitantly, the absorption band.

In some non-limiting examples, material surrounding such regions, whether underlying them (such that the particle structures 61 may be deposited onto the exposed layer surface 11 thereof) or subsequently disposed on an exposed layer surface 11 thereof, may impact the optical effects that the particle structures 61 impact on the transmission of photons and/or signals through the regions.

It may be postulated that disposing the particle structures 61 on, and/or in physical contact with, and/or proximate to, an exposed layer surface 11 of an NIC 410 that may be comprised of a low refractive index n material, may, in some non-limiting examples, shift the absorption spectrum of the particle structures 61.

Since the at least one particle structure 61 may be arranged to be on, and/or in physical contact with, and/or proximate to, the NIC 410, the device 400 may be configured such that the absorption spectrum of particle structures 61 may be tuned and/or modified, due to the presence of the NIC 410. In some non-limiting examples, the device 400 may be configured such that such absorption spectrum may be tuned and/or modified, due to the presence of the NIC 410, such that such absorption spectrum may substantially overlap and/or may not overlap with at least a part of the EM spectrum, including without limitation, the visible spectrum, the UV spectrum, and/or the IR spectrum. In some non-limiting examples, the device 400 may be configured such that such absorption spectrum may be tuned and/or modified, due to the presence of the NIC 410 or the low-index layer, such that such absorption spectrum may substantially overlap with at least a part of the UVA spectrum, thereby attenuating transmission of UVA light or signal therethrough.

In some non-limiting examples, the deposited material 426 may comprise a metal having a bond dissociation energy, of less than about: 300 kJ/mol, 200 kJ/mol, 165 kJ/mol, 150 kJ/mol, 50 kJ/mol, or 20 kJ/mol.

In some non-limiting examples, the deposited material 426 may comprise a metal having an electronegativity that is less than about: 1.4, 1.3, or 1.2.

In some non-limiting examples, the deposited material 426 may comprise an element selected from potassium (K), sodium (Na), lithium (Li), barium (Ba), cesium (Cs), ytterbium (Yb), silver (Ag), gold (Au), copper (Cu), aluminum (AI), magnesium (Mg), zinc (Zn), cadmium (Cd), tin (Sn), or yttrium (Y). In some non-limiting examples, the element may comprise K, Na, Li, Ba, Cs, Yb, Ag, Au, Cu, Al, and/or Mg. In some non-limiting examples, the element may comprise Cu, Ag, and/or Au. In some non-limiting examples, the element may be Cu. In some non-limiting examples, the element may be Al. In some non-limiting examples, the element may comprise Mg, Zn, Cd, and/or Yb. In some non-limiting examples, the element may comprise Mg, Ag, Al, Yb, and/or Li. In some non-limiting examples, the element may comprise Mg, Ag, and/or Yb. In some non-limiting examples, the element may comprise Mg, and/or Ag. In some non-limiting examples, the element may be Ag.

In some non-limiting examples, the deposited material 426 may be a pure metal. In some non-limiting examples, the deposited material 426 may be pure Ag or substantially pure Ag. In some non-limiting examples, the substantially pure Ag may have a purity of at least: about 95%, about 99%, about 99.9%, about 99.99%, about 99.999%, or about 99.9995%. In some non-limiting examples, the deposited material 426 may be pure Mg or substantially pure Mg. In some non-limiting examples, the substantially pure Mg may have a purity of at least: about 95%, about 99%, about 99.9%, about 99.99%, about 99.999%, or about 99.9995%.

In some non-limiting examples, the deposited material 426 may comprise an alloy. In some non-limiting examples, the alloy may be an Ag-containing alloy, an Mg-containing alloy, or an AgMg-containing alloy. In some non-limiting examples, the AgMg-containing alloy may have an alloy composition that may range from 1:10 (Ag:Mg) to about 10:1 by volume.

In some non-limiting examples, the deposited material 426 may comprise other metals in place of, and/or in combination with, Ag. In some non-limiting examples, the deposited material 426 may comprise an alloy of Ag with at least one other metal. In some non-limiting examples, the deposited material 426 may comprise an alloy of Ag with Mg, and/or Yb. In some non-limiting examples, such alloy may be a binary alloy having a composition from about 5 vol. % Ag to about 95 vol. % Ag, with the remainder being the other metal. In some non-limiting examples, the deposited material 426 may comprise Ag and Mg. In some non-limiting examples, the deposited material 426 may comprise an Ag:Mg alloy having a composition from about 1:10 to about 10:1 by volume. In some non-limiting examples, the deposited material 426 may comprise Ag and Yb. In some non-limiting examples, the deposited material 426 may comprise a Yb:Ag alloy having a composition from about 1:20 to about 10:1 by volume. In some non-limiting examples, the deposited material 426 may comprise Mg and Yb. In some non-limiting examples, the deposited material 426 may comprise an Mg:Yb alloy. In some non-limiting examples, the deposited material 426 may comprise Ag, Mg, and Yb. In some non-limiting examples, the deposited material 426 may comprise an Ag:Mg:Yb alloy.

In some non-limiting examples, the deposited material 426 may comprise at least one additional element. In some non-limiting examples, such additional element may be a non-metallic element. In some non-limiting examples, the non-metallic element may be O, S, N, or C. It will be appreciated by those having ordinary skill in the relevant art that, in some non-limiting examples, such additional element(s) may be incorporated on a surface of the deposited material 426, as a contaminant, due to the presence of such additional element(s) in the source material, equipment used for deposition, and/or the vacuum chamber environment. In some non-limiting examples, the concentration of such additional element(s) may be limited to be below a threshold concentration. In some non-limiting examples, such additional element(s) may form a compound together with other element(s) of the deposited material 426. In some non-limiting examples, a concentration of the non-metallic element in the deposited material 426 may be less than about: 1%, 0.1%, 0.01%, 0.001%, 0.0001%, 0.00001%, 0.000001%, or 0.0000001%. In some non-limiting examples, the deposited material 426 may have a composition in which a combined amount of O and C therein is less than about: 10%, 5%, 1%, 0.1%, 0.01%, 0.001%, 0.0001%, 0.00001%, 0.00001%, or 0.0000001%.

It has now been, somewhat surprisingly, found that reducing a concentration of certain non-metallic elements in the deposited material 426, particularly in cases where the deposited material 426 is substantially comprised of metal(s) and/or metal alloy(s), may facilitate selective deposition of the at least one particle structure 61. Without wishing to be bound by any particular theory, it may be postulated that certain non-metallic elements, such as, by way of non-limiting examples, O and/or C, when present in the vapour flux of the deposited material 426 and/or in the deposition chamber and/or environment, may be deposited onto the surface of the NIC 410 to act as nucleation sites for the metallic element(s) of the deposited material 426. It may be postulated that reducing a concentration of such non-metallic elements that could act as nucleation sites may facilitate reducing an amount of deposited material 426 deposited on the exposed layer surface 11 of the NIC 410.

In some non-limiting examples, the deposited material 426 and the underlying layer may comprise a common metal.

In some non-limiting examples, the NIC 410, and/or the NIC material 416, in some non-limiting examples, when deposited as a film and/or coating in a form, and under circumstances similar to the deposition of the NIC 410 within the device 400, may have a surface energy Y1 that may be less than a surface energy Y2 of the deposited material 426, in some non-limiting examples, when deposited in a form, and under circumstances similar to the deposition of the at least one particle structure 61, within the device 400.

In some non-limiting examples, a quotient of Y2/Y1 may be at least about: 1, 5, 10, or 20.

In some non-limiting examples, a surface coverage C1 of an area of the NIC 410 by the at least one particle structure 61 thereon, may be no more than a maximum threshold percentage coverage.

In some non-limiting examples, an assessment of the surface coverage may be performed, including without limitation, by measuring and/or calculating, the presence of the at least one particle structure 61, using a variety of imaging techniques, including without limitation, transmission electron microscopy (TEM), atomic force microscopy (AFM) and/or scanning electron microscopy (SEM).

In some non-limiting examples, an assessment of the surface coverage may be performed, including without limitation, by measuring and/or calculating, the presence of the at least one particle structures 61, using a variety of imaging techniques, including without limitation, TEM, AFM, and/or SEM.

In some non-limiting examples, at least one of such criteria may be quantified by a numerical metric. In some non-limiting examples, such a metric may be a calculation of a dispersity D that describes the distribution of particle (area) sizes of the at least one particle structure 61 in such regions, in which:

$$D = \frac{\overline{{S}_{s}}}{\overline{{S}_{n}}}$$

$$where$$

$$\overline{{S}_{s}} = \frac{{\sum }_{i = 1}^{n} {S}_{i}^{2}}{{\sum }_{i = 1}^{n} {S}_{i}} , \overline{{S}_{n}} = \frac{{\sum }_{i = 1}^{n} {S}_{i}}{n} ,$$

Sᵢ is the (area) size of the i^{th} particle,

S̅ₙ̅ is the number average of the particle (area) sizes and

S̅ₛ̅ is the (area) size average of the particle (area) sizes.

Those having ordinary skill in the relevant art will appreciate that the dispersity D is roughly analogous to a polydispersity index (PDI) and that these averages are roughly analogous to the concepts of number average molecular weight and weight average molecular weight familiar in organic chemistry, but applied to an (area) size, as opposed to a molecular weight of a sample particle structure 61.

Those having ordinary skill in the relevant will also appreciate that in the context of the calculation of the dispersity D, the concept of an (area) size may be used to reflect that each particle structure 61 represents a three-dimensional volumetric concept along three axes, namely the longitudinal axis and a pair or lateral axes.

In some non-limiting examples, the dispersity D and/or the number average of the particle (area) size and the (area) size average of the particle (area) size may involve a calculation of at least one of the number average of the particle diameters and the (area) size average of the particle diameters:

$$\overline{{d}_{n}} = 2 \sqrt{\frac{\overline{{S}_{n}}}{π}} , \overline{{d}_{s}} = 2 \sqrt{\frac{\overline{{S}_{s}}}{π}}$$

In some non-limiting examples, the deposited material 426, including without limitation as particle structures 61, may be deposited by a mask-free and/or open mask deposition process.

In some non-limiting examples, the at least one particle structure 61 and the underlying layer together may form at least part of an emissive electrode 404, 406 of a light emitting device, including without limitation, an OLED. In some non-limiting examples, the at least one particle structure 61 and the underlying layer together may form at least part of a cathode thereof.

In some non-limiting examples, the at least one particle structure 61 may be deposited in a pattern across the lateral extent of the NIC 410 using a fine metal mask (FMM).

In some non-limiting examples, the at least one particle structure 61 may be disposed in a pattern that may be defined by at least one region therein that is substantially devoid of a closed coating of the deposited material 426. In some non-limiting examples, the at least one region may separate the deposited material 426 into a plurality of discrete fragments thereof. In some non-limiting examples, the plurality of discrete fragments of the deposited material 426 may be physically spaced apart from one another in the lateral aspect thereof. In some non-limiting examples, at least two of such plurality of discrete fragments of the deposited material 426 may be electrically coupled. In some non-limiting examples, at least two of such plurality of discrete fragments of the deposited material 426 may be each electrically coupled to a common conductive layer or coating, including without limitation, the underlying layer, to allow the flow of electrical current between them. In some non-limiting examples, at least two of such plurality of discrete fragments of the deposited material 426 may be electrically insulated from one another.

In some non-limiting examples, the characteristics of such at least one particle structure 61 may be assessed, in some non-limiting examples, somewhat arbitrarily, according to at least one of several criteria, including without limitation, a characteristic size, size distribution, shape, configuration, coverage, deposited distribution, dispersity, and/or a presence and/or extent of aggregation instances of deposited material 426, formed on a portion of the exposed layer surface 11 of the underlying layer.

In some non-limiting examples, an assessment of the at least one particle structure 61 according to such at least one criterion, may be performed on, including without limitation, by measuring and/or calculating, at least one attribute thereof, using a variety of imaging techniques, including without limitation, TEM, AFM and/or SEM.

Those having ordinary skill in the relevant art will appreciate that such an assessment may depend, to a greater and/or lesser extent, by the extent, of the exposed layer surface 11 under consideration, which in some non-limiting examples may comprise an area and/or region thereof. In some non-limiting examples, the at least one particle structure 61 may be assessed across the entire extent, in a first lateral aspect, and/or a second lateral aspect that is substantially transverse thereto, of the exposed layer surface 11. In some non-limiting examples, the at least one particle structure 61 may be assessed across an extent that comprises at least one applied observation window.

In some non-limiting examples, the at least one observation window may be located at a perimeter, interior location, and/or grid coordinate of the lateral aspect of the exposed layer surface 11. In some non-limiting examples, a plurality of the at least one observation windows may be used in assessing the at least one particle structure 61.

In some non-limiting examples, the observation window may correspond to a field of view of an imaging technique applied to assess the at least one particle structure 61, including without limitation, TEM, AFM, and/or SEM. In some non-limiting examples, the observation window may correspond to a given level of magnification, including without limitation: 2.00 μm, 1.00 μm, 500 nm, or 200 nm.

In some non-limiting examples, the assessment of the at least one particle structure 61, including without limitation, at least one observation window used, of the exposed layer surface 11 thereof, may involve calculating and/or measuring, by any number of mechanisms, including without limitation, manual counting, and/or known estimation techniques, which may, in some non-limiting examples, may comprise curve, polygon, and/or shape fitting techniques.

In some non-limiting examples, the assessment of the at least one particle structure 61, including without limitation, at least one observation window used, of the exposed layer surface 11 thereof, may involve calculating and/or measuring an average, median, mode, maximum, minimum, and/or other probabilistic, statistical, and/or data manipulation of a value of the calculation and/or measurement.

In some non-limiting examples, one of the at least one criterion by which such at least one particle structure 61 may be assessed, may be a surface coverage of the deposited material 426 in the lateral aspect of the non-emissive region(s) 409, including without limitation, the entirety of the second portion 312. In some non-limiting examples, the surface coverage may be represented by a (non-zero) percentage coverage by such deposited material 426 of such regions. In some non-limiting examples, the percentage coverage may be compared to a maximum threshold percentage coverage.

In some non-limiting examples, a (part of a) deposited layer 320 having surface coverage that may be substantially no more than the maximum threshold percentage coverage, may result in a manifestation of different optical characteristics that may be imparted by such part of such regions, to photons passing therethrough, whether transmitted entirely through the device 400 and/or emitted thereby, relative to photons passing through a part of such regions having a surface coverage that substantially exceeds the maximum threshold percentage coverage.

In some non-limiting examples, one measure of a surface coverage of an amount of an electrically conductive material on a surface may be a (light) transmittance, since in some non-limiting examples, electrically conductive materials, including without limitation, metals, including without limitation: Ag, Mg, and/or Yb, attenuate and/or absorb photons.

Those having ordinary skill in the relevant art will appreciate that in some non-limiting examples, surface coverage may be understood to encompass one or both of particle size, and deposited density. Thus, in some non-limiting examples, two or more of these three criteria may be positively correlated. Indeed, in some non-limiting examples, a criterion of low surface coverage may comprise some combination of a criterion of low deposited density with a criterion of low particle size.

In some non-limiting examples, one of the at least one criterion by which such regions may be assessed, may be a characteristic size of the constituent particle structures 61.

In some non-limiting examples, the at least one particle structure 61 may have a characteristic size S1 that is no more than a maximum threshold size. Non-limiting examples of the characteristic size S1 may include height, width, length, and/or diameter.

In some non-limiting examples, substantially all of the particle structures 61, may have a characteristic size S1 that lies within a specified range.

In some non-limiting examples, such characteristic size S1 may be characterized by a characteristic length, which in some non-limiting examples, may be considered a maximum value of the characteristic size. In some non-limiting examples, such maximum value may extend along a major axis of the particle structure 61. In some non-limiting examples, the major axis may be understood to be a first dimension extending in a plane defined by the plurality of lateral axes. In some non-limiting examples, a characteristic width may be identified as the value of the characteristic size of the particle structure 61 that extends along a minor axis of the particle structure 61. In some non-limiting examples, the minor axis may be understood to be a second dimension extending in the same plane but substantially transverse to the major axis.

In some non-limiting examples, the characteristic length of the at least one particle structure 61, along the first dimension, may be less than the maximum threshold size.

In some non-limiting examples, the characteristic width of the at least one particle structure 61, along the second dimension, may be less than the maximum threshold size.

In some non-limiting examples, the size of the particle structures 61 may be assessed by calculating and/or measuring a characteristic size of such at least one particle structure 61, including without limitation, a mass, volume, length of a diameter, perimeter, major, and/or minor axis thereof.

In some non-limiting examples, one of the at least one criterion by which such deposited layer 320 may be assessed, may be a deposited density thereof.

In some non-limiting examples, the characteristic size of the particle structure 61 may be compared to a maximum threshold size.

In some non-limiting examples, the deposited density of the particle structures 61 may be compared to a maximum threshold deposited density.

In some non-limiting examples, the particle structures 61 may have a substantially round shape. In some non-limiting examples, the particle structures 61 may have a substantially spherical shape.

In some non-limiting examples, the particle structures 61 may have a maximum threshold size of less than about 200 nm. By way of non-limiting example, such dimension may correspond to a width, length, diameter, and/or height of individual particle. In some non-limiting examples, the particles of the particle structures 61 have a diameter of: about 1-200 nm, about 1-160 nm, about 1-100 nm, about 1-50 nm, about 1-30 nm, or about 1-20 nm.

In some non-limiting examples, the particles of the particle structures 61 have a mean and/or median dimension of: about 1-200 nm, about 1-150 nm, about 1-100 nm, about 1-50 nm, about 1-30 nm, about 1-20 nm, about 5-18 nm, or about 8-15 nm. By way of non-limiting example, such mean and/or median dimension may correspond to the mean diameter and/or the median diameter of particles.

In some non-limiting examples, a percentage of the exposed layer surface underlying the particle structures 61, by way of non-limiting example, in a given area, may be less than: about 35%, about 30%, about 25%, about 20%, about 18%, about 15%, about 13%, or about 10%. In some non-limiting examples, a percentage of the exposed layer surface underlying the particle structures 61, by way of non-limiting example, in a given area, may be: about 10-35%, about 10-30%, about 15-25%, or about 18-25%.

For purposes of simplification, in some non-limiting examples, it may be assumed that the longitudinal extent of each particle structure 61 may be substantially the same (in any event, it cannot be directly measured from a plan view SEM image) so that the (area) size of the particle structure 61 may be represented as a two-dimensional area coverage along the pair of lateral axes. In the present disclosure, a reference to an (area) size may be understood to refer to such two-dimensional concept, and to be differentiated from a size (without the prefix “area”) that may be understood to refer to a one-dimensional concept, such as a linear dimension.

Indeed, in some early investigations, it appears that, in some non-limiting examples, the longitudinal extent, along the longitudinal axis, of such particle structures 61, may tend to be small relative to the lateral extent (along at least one of the lateral axes), such that the volumetric contribution of the longitudinal extent thereof may be much less than that of such lateral extent. In some non-limiting examples, this may be expressed by an aspect ratio (a ratio of the longitudinal extent to a lateral extent) that may be less than 1. In some non-limiting examples, such aspect ratio may be about: 1:10, 1:20, 1:50, 1:75, and 1:300.

In this regard, the assumption set out above that the longitudinal extent is substantially the same and can be ignored, to represent the particle structure 61 as a two-dimensional area coverage may be appropriate.

Those having ordinary skill in the relevant art will appreciate, having regard to the non-determinative nature of the deposition process, especially in the presence of defects and/or anomalies on the exposed layer surface 11 of the underlying material, including without limitation, heterogeneities, including without limitation, a step edge, a chemical impurity, a bonding site, a kink, and/or a contaminant thereon, and consequently the formation of particle structures 61 thereon, the non-uniform nature of coalescence thereof as the deposition process continues, and in view of the uncertainty in the size and/or position of observation windows, as well as the intricacies and variability inherent in the calculation and/or measurement of their size, spacing, deposited density, degree of aggregation, and the like, there may be considerable variability in terms of the features and/or topology within observation windows.

In the present disclosure, for purposes of simplicity of illustration, certain details of deposited materials, including without limitation, thickness profiles and/or edge profiles of layer(s) have been omitted.

In some non-limiting examples, the exposed layer surface 11 of the device 400 within the lateral aspect of the non-emissive region(s) 409, including without limitation, the entirety of the second portion 312, may be substantially devoid of any particle structures 61 of the deposited material 426.

### Second Electrode

the same time, because the NIC 410 has been restricted to the entirety of the second portion 312, and/or within the lateral aspect of the non-emissive region(s) 409 of the first portion 311, in some non-limiting examples, the exposed layer surface 11 of the device 400 within the lateral aspect of the emissive region(s) 407 of the first portion 311 may comprise the at least one semiconducting layer 405. Accordingly, within such lateral aspect of the emissive region(s) 407 of the first portion 311, the vapor flux of the deposited material 426 incident on the exposed layer surface 11, may form a closed coating of the deposited material 426, which may serve as, and/or form part of, the second electrode 406.

In some non-limiting examples, the second electrode 406 may extend partially over the NIC 410 in a transition region 417.

Thus, in some non-limiting examples, the NIC 410 may serve one or more purposes, namely: to substantially preclude the deposition of the deposited material 426 as (part of) the second electrode 406 in the second portion 312; to allow the (selective and/or patterned) deposition of the deposited material 426 as (part of) the second electrode 406 in parts (in some non-limiting examples, corresponding to the lateral aspect of the emissive region(s) 407) of the first portion 311; and/or in some non-limiting examples, to provide a base for the deposition of at least one particle structure 61 where the NIC 410 has been deposited; all without employing a mask during the deposition of the deposited material 426.

### Low-Index Coating

In some non-limiting examples, at least one low-index coating is disposed in the at least one blind hole region 313. In some non-limiting examples, the at least one low-index coating is arranged on a side of the substrate 10 opposite to the at least one under-display component 330. In some non-limiting examples, the at least one low-index coating is disposed on, or adjacent to, the at least one semiconducting layer 405.

The at least one low-index coating generally exhibits a relatively low refractive index n in at least a part of the visible spectrum. By way of non-limiting example, the refractive index of the low-index coating may be no more than about: 1.55, 1.5, 1.45, 1.43, 1.4, 1.39, 1.37, 1.35, 1.32, 1.3, or 1.25. In some non-limiting examples, the refractive index n of the low-index coating is between about: 1.2-1.55, 1.2-1.5, 1.25-1.45, or 1.25-1.4. In some non-limiting examples, where the low-index coating may have a refractive index n of less than about: 1.4, 1.37, or 1.35 at a wavelength of about 550 nm may be particularly advantageous for enhancing light transmittance through the at least one blind hole region 313.

Without wishing to be bound by any particular theory, it has been found that providing the low-index coating may, at least in some devices 400, enhance transmission of external light through the at least one blind hole region 313 thereof. By way of non-limiting example, it has now been found, somewhat surprisingly, that a display panel 310 having a low-index coating, that has a lower refractive index n than, by way of non-limiting example, a typical capping layer (CPL) used in an OLED, may exhibit enhanced light transmission relative to an equivalent display panel without the presence of such low-index coating. This is particularly surprising given that those having ordinary skill in the relevant art may reasonably expect that including a low-index coating would create an interface between the low-index coating and an adjacent higher refractive index n layer that might cause light to be reflected, thus decreasing the amount of transmitted light through such device. In at least one non-limiting example, it was found that a device in which a 15 nm thick low-index coating was disposed between a CPL and a semiconductor layer 405 exhibited approximately 5% higher light transmittance, measured at a wavelength of 500 nm, compared to another device in which no such low-index coating was provided.

In some non-limiting examples, the low-index layer may have an extinction coefficient k that may be less than about 0.01 for photons at a wavelength that exceeds at least about: 600 nm, 500 nm, 460 nm, 420 nm, or 410 nm. In this way, for example, the low-index layer may not substantially attenuate and/or absorb light transmitted through the display panel 310.

In some non-limiting examples, the low-index layer may be and/or act as an NIC layer 310.

The exposed layer surface 11 of an uppermost (last deposited) one of the at least one low-index coating may be defined as an interface surface. In some non-limiting examples, a high-index medium may be disposed on the interface surface.

In some non-limiting examples, the high-index medium may be provided in the form of a physical high-index coating, including without limitation, a covering layer that may be deposited upon the device 400 as part of the manufacturing process. In some non-limiting examples, the high-index coating may comprise lithium fluoride (LiF).

The refractive index n of the at least one low-index coating may be lower than that of the high-index medium, including without limitation, the high-index coating, in some non-limiting examples, in at least a part of the visible spectrum.

While in some non-limiting examples, the refractive index n of the at least one low-index coating may be considered to be low in comparison with typical materials used in a typical opto-electronic device, those having ordinary skill in the relevant art will appreciate that, for purposes of the present disclosure, the refractive index n of the at least one low-index coating is not necessarily so limited, provided that the refractive index n of the at least one low-index coating is less than that of the high-index medium.

Further, in some non-limiting examples, the device 400 may be provided, at the interface surface, with an air gap and/or air interface, whether during, or subsequent to, manufacture, and/or in operation, where the at least one low-index coating may have a refractive index n that is lower than that of air, which is considered to have a refractive index that is typically slightly above 1.0.

### UVA-Absorbing Coating

In some non-limiting examples, a UVA-absorbing coating may be disposed in the at least one blind hole region 313. Such UVA-absorbing coating may generally absorb light in the UVA spectrum.

In at least some applications, it may be particularly beneficial to provide such UVA-absorbing coating to reduce or mitigate transmission of UVA light to the under-display component 330. By way of non-limiting example, the presence of such UVA-absorbing coating may enhance the image quality captured using the under-display component 330 by reducing interference caused by UVA light.

In some non-limiting examples, such UVA-absorbing coating may be arranged on a side of the substrate 10 that is opposite to the at least one under-display component 330.

In some non-limiting examples, such UVA-absorbing coating may be disposed on, and/or adjacent to, the at least one semiconducting layer 405.

In some non-limiting examples, such UVA-absorbing coating may be disposed on, and/or in direct contact with, the at least one low-index coating.

In some non-limiting examples, the UVA-absorbing coating may comprise the at least one particle structure 61.

### Covering Layer

In some non-limiting examples, an exposed layer surface 11 of the second electrode 40 and the NIC 410 may be overlaid with one or more layers and/or coatings, including without limitation, a barrier coating 520, glass cap and/or thin film encapsulation (TFE) layer, a polarizer 530, other layers 540, including without limitation, an optically clear adhesive (OCA) and/or a touchscreen material) and/or a glass covering 550 (in some non-limiting examples, collectively “covering layer”) to form the at least one face 301 of the display panel 310.

It has been reported in Fusella et al., “Plasmonic enhancement of stability and brightness in organic light-emitting devices”, Nature 2020, 585, at 379-382 (“Fusella et al.”), that the stability of an OLED device may be enhanced by incorporating an NP-based out-coupling layer above the cathode layer to extract energy from the plasmon modes. The NP-based out-coupling layer was fabricated by spin-casting 20 nm cubic Ag NPs on top of an organic layer on top of a cathode.

However, since most commercial OLED devices are fabricated using vacuum-based processing, spin-casting from solution may not constitute an appropriate mechanism for forming such an NP-based out-coupling layer above the cathode.

The inventors have discovered that such an NP-based out-coupling layer (such as, without limitation, at least one of the barrier coating 520, glass cap and/or TFE layer, polarizer 530, other layers 540, and/or a glass covering) above the cathode may be fabricated in vacuum (and thus, may be suitable for us in a commercial OLED fabrication process), by depositing a metal deposited material 426 onto an NIC 410, which in some non-limiting examples, may be, and/or be deposited on, the cathode. Such process may avoid the use of solvents or other wet chemicals that may cause damage to the OLED device and/or may adversely impact device reliability.

In some non-limiting examples, to substantially increase transmissivity through the at least one blind hole region 313, the polarizer 530 may be formed so as to provide substantially no polarization across the lateral aspect of the at least one blind hole region 313 of the second portion 312 of the device 400, including without limitation, having an aperture therein corresponding thereto.

In some non-limiting examples, the optical response discussed previously in respect of photon-absorbing coatings, may include absorption of photons incident thereon, thereby reducing reflection. In some non-limiting examples, the absorption may be concentrated in a range of the EM spectrum, including without limitation, the visible spectrum and/or a sub-range thereof. In some non-limiting examples, employing a photon-absorbing layer as part of an opto-electronic device may reduce reliance on the polarizer 530 therein.

Those having ordinary skill in the relevant art will appreciate that although not shown, the absence of the first electrode 401 within the lateral aspect of the at least one blind hole region 313 of the second portion 312 of the device 400 may cause the at least one semiconducting layer 405 and/or the NIC 410 to be deposited at a lower level than shown, with the result that a gap may be formed within the lateral aspect of the at least one blind hole region 313 of the second portion 312 of the device at some layer(s) below the glass covering.

To reduce any undesirable optical effects created thereby, in some non-limiting examples, an index-matching filler material (not shown) may be deposited at some layer(s) between the substrate 10 and the glass covering to fill such gap. In some non-limiting examples such filler material may comprise an optical medium for reducing optical interference, including without limitation caused by internal reflection of EM signals within the display, including without limitation, cover glass and/or frit glass. In some non-limiting examples, the optical medium may have a refractive index substantially matching that of at least one of the at least one semiconducting layer 405, the substrate 10 and/or glass.

### TECHNICAL

An organic opto-electronic device may encompass any opto-electronic device where one or more active layers and/or strata thereof are formed primarily of an organic (carbon-containing) material, and more specifically, an organic semiconductor material.

Where the opto-electronic device emits photons through a luminescent process, the device may be considered an electro-luminescent device. In some non-limiting examples, the electro-luminescent device may be an organic light-emitting diode (OLED) device. In some non-limiting examples, the electro-luminescent device may be part of an electronic device. By way of non-limiting example, the electro-luminescent device may be an OLED lighting panel or module, and/or an OLED display or module of a computing device, such as a smartphone, a tablet, a laptop, an e-reader, and/or of some other electronic device such as a monitor and/or a television set.

In some non-limiting examples, the opto-electronic device may be an organic PD (OPV) device that converts photons into electricity. In some non-limiting examples, the opto-electronic device may be an electro-luminescent QD device.

In the present disclosure, unless specifically indicated to the contrary, reference will be made to OLED devices, with the understanding that such disclosure could, in some examples, equally be made applicable to other opto-electronic devices, including without limitation, an OPV and/or QD device, in a manner apparent to those having ordinary skill in the relevant art.

The structure of such devices may be described from each of two aspects, namely from a cross-sectional aspect and/or from a lateral (plan view) aspect.

In the present disclosure, a directional convention may be followed, extending substantially normally to the lateral aspect described above, in which the substrate may be considered to be the “bottom” of the device, and the layers may be disposed on “top” of the substrate. Following such convention, the second electrode may be at the top of the device shown, even if (as may be the case in some examples, including without limitation, during a manufacturing process, in which one or more layers may be introduced by means of a vapor deposition process), the substrate may be physically inverted, such that the top surface, in which one of the layers, such as, without limitation, the first electrode, is to be disposed, may be physically below the substrate, so as to allow the deposition material (not shown) to move upward and be deposited upon the top surface thereof as a thin film.

In the context of introducing the cross-sectional aspect herein, the components of such devices may be shown in substantially planar lateral strata. Those having ordinary skill in the relevant art will appreciate that such substantially planar representation is for purposes of illustration only, and that across a lateral extent of such a device, there may be localized substantially planar strata of different thicknesses and dimension, including, in some non-limiting examples, the substantially complete absence of a layer, and/or layer(s) separated by non-planar transition regions (including lateral gaps and even discontinuities). Thus, while for illustrative purposes, the device is shown below in its cross-sectional aspect as a substantially stratified structure, in the plan view aspect discussed below, such device may illustrate a diverse topography to define features, each of which may substantially exhibit the stratified profile discussed in the cross-sectional aspect.

In the present disclosure, the terms “layer” and “strata” may be used interchangeably to refer to similar concepts.

The thickness of each layer shown in the figures is illustrative only and not necessarily representative of a thickness relative to another layer.

For purposes of simplicity of description, in the present disclosure, a combination of a plurality of elements in a single layer may be denoted by a colon “:”, while a plurality of (combination(s) of) elements comprising a plurality of layers in a multi-layer coating may be denoted by separating two such layers by a slash “/”. In some non-limiting examples, the layer after the slash may be deposited after and/or on the layer preceding the slash.

For purposes of illustration, an exposed layer surface of an underlying material, onto which a coating, layer and/or material is deposited, may be understood to be a surface of such underlying material that is presented for deposition of the coating, layer and/or material thereon, at the time of deposition.

Those having ordinary skill in the relevant art will appreciate that when a component, a layer, a region, and/or a portion thereof, is referred to as being “formed”, “disposed”, and/or “deposited” on and/or over another underlying material, component, layer, region, and/or portion, such formation, disposition, and/or deposition may be directly and/or indirectly on an exposed layer surface (at the time of such formation, disposition, and/or deposition) of such underlying material, component, layer, region, and/or portion, with the potential of intervening material(s), component(s), layer(s), region(s), and/or portion(s) therebetween.

While the present disclosure discusses thin film formation, in reference to at least one layer or coating, in terms of vapor deposition, those having ordinary skill in the relevant art will appreciate that, in some non-limiting examples, various components of the device may be selectively deposited using a wide variety of techniques, including without limitation, evaporation (including without limitation, thermal evaporation and/or electron beam evaporation), photolithography, printing (including without limitation, ink jet and/or vapor jet printing, reel-to-reel printing and/or micro-contact transfer printing), PVD (including without limitation, sputtering), chemical vapor deposition (CVD) (including without limitation, plasma-enhanced CVD (PECVD), and/or organic vapor phase deposition (OVPD)), laser annealing, laser-induced thermal imaging (LITI) patterning, atomic-layer deposition (ALD), coating (including without limitation, spin-coating, di coating, line coating, and/or spray coating), and/or combinations thereof.

Some processes may be used in combination with a shadow mask, which may, in some non-limiting examples, may be an open mask and/or fine metal mask (FMM), during deposition of any of various layers and/or coatings to achieve various patterns by masking and/or precluding deposition of a deposited material on certain parts of a surface of an underlying material exposed thereto.

In the present disclosure, the terms “evaporation” and/or “sublimation” may be used interchangeably to refer generally to deposition processes in which a source material is converted into a vapor, including without limitation, by heating, to be deposited onto a target surface in, without limitation, a solid state. As will be understood, an evaporation process may be a type of PVD process where one or more source materials are evaporated and/or sublimed under a low pressure (including without limitation, a vacuum) environment to form vapor monomers and deposited on a target surface through de-sublimation of the one or more evaporated source materials. A variety of different evaporation sources may be used for heating a source material, and, as such, it will be appreciated by those having ordinary skill in the relevant art, that the source material may be heated in various ways. By way of non-limiting example, the source material may be heated by an electric filament, electron beam, inductive heating, and/or by resistive heating. In some non-limiting examples, the source material may be loaded into a heated crucible, a heated boat, a Knudsen cell (which may be an effusion evaporator source), and/or any other type of evaporation source.

In some non-limiting examples, a deposition source material may be a mixture. In some non-limiting examples, at least one component of a mixture of a deposition source material may be not be deposited during the deposition process (or, in some non-limiting examples, be deposited in a relatively small amount compared to other components of such mixture).

In the present disclosure, a reference to a layer thickness, a film thickness, and/or an average layer and/or film thickness, of a material, irrespective of the mechanism of deposition thereof, may refer to an amount of the material deposited on a target exposed layer surface, which corresponds to an amount of the material to cover the target surface with a uniformly thick layer of the material having the referenced layer thickness. By way of non-limiting example, depositing a layer thickness of 10 nm of material may indicate that an amount of the material deposited on the surface may correspond to an amount of the material to form a uniformly thick layer of the material that is 10 nm thick. It will be appreciated that, having regard to the mechanism by which thin films are formed discussed above, by way of non-limiting example, due to possible stacking or clustering of monomers, an actual thickness of the deposited material may be non-uniform. By way of non-limiting example, depositing a layer thickness of 10 nm may yield some parts of the deposited material having an actual thickness greater than 10 nm, or other parts of the deposited material having an actual thickness less than 10 nm. A certain layer thickness of a material deposited on a surface may thus correspond, in some non-limiting examples, to an average thickness of the deposited material across the target surface.

In the present disclosure, a reference to a reference layer thickness may refer to a layer thickness of the deposited material, also referred to herein as the conductive coating material, that may be deposited on a reference surface exhibiting a high initial sticking probability or initial sticking coefficient S₀ (that is, a surface having an initial sticking probability S₀ that is about and/or close to 1.0). The reference layer thickness may not indicate an actual thickness of the deposited material deposited on a target surface (such as, without limitation, a surface of an NIC). Rather, the reference layer thickness may refer to a layer thickness of the deposited material that would be deposited on a reference surface, in some non-limiting examples a surface of a quartz crystal positioned inside a deposition chamber for monitoring a deposition rate and the reference layer thickness, upon subjecting the target surface and the reference surface to identical vapor flux of the deposited material for the same deposition period. Those having ordinary skill in the relevant art will appreciate that in the event that the target surface and the reference surface are not subjected to identical vapor flux simultaneously during deposition, an appropriate tooling factor may be used to determine and/or to monitor the reference layer thickness.

In the present disclosure, a reference deposition rate may refer to a rate at which a layer of the deposited material would grow on the reference surface, if it were identically positioned and configured within a deposition chamber as the sample surface.

In the present disclosure, a reference to depositing a number X of monolayers of material may refer to depositing an amount of the material to cover a desired area of an exposed layer surface with X single layer(s) of constituent monomers of the material, such as, without limitation, in a closed coating.

In the present disclosure, a reference to depositing a fraction 1/X monolayer of a material may refer to depositing an amount of the material to cover a fraction 0.X of a desired area of a surface with a single layer of constituent monomers of the material. Those having ordinary skill in the relevant art will appreciate that due to, by way of non-limiting example, possible stacking and/or clustering of monomers, an actual local thickness of a deposited material across a desired area of a surface may be non-uniform. By way of non-limiting example, depositing 1 monolayer of a material may result in some local regions of the desired area of the surface being uncovered by the material, while other local regions of the desired area of the surface may have multiple atomic and/or molecular layers deposited thereon.

In the present disclosure a target surface (and/or target region(s) thereof) may be considered to be “substantially devoid of”, “substantially free of”, and/or “substantially uncovered by” a material if there is a substantial absence of the material on the target surface as determined by any suitable determination mechanism.

In the present disclosure, the terms “sticking probability” and “sticking coefficient” may be used interchangeably.

In the present disclosure, the term “nucleation” may reference a nucleation stage of a thin film formation process, in which monomers in a vapor phase condense onto a surface to form nuclei.

In the present disclosure, in some non-limiting examples, as the context dictates, the terms “patterning coating” and “patterning material” may be used interchangeably to refer to similar concepts, and references to an patterning coating herein, in the context of being selectively deposited to pattern a conductive coating may, in some non-limiting examples, be applicable to a NIC material in the context of selective deposition thereof to pattern a deposited material and/or an electrode coating material.

Similarly, in some non-limiting examples, as the context dictates, the term “patterning coating” and “patterning material” may be used interchangeably to refer to similar concepts, and reference to an NPC herein, in the context of being selectively deposited to pattern a conductive coating may, in some non-limiting examples, be applicable to a NPC material in the context of selective deposition thereof to pattern an electrode coating.

While a patterning material may be either nucleation-inhibiting or nucleation-promoting, in the present disclosure, unless the context dictates otherwise, a reference herein to a patterning material is intended to be a reference to an NIC.

In some non-limiting examples, reference to a patterning material may signify a coating having a specific composition as described herein.

In the present disclosure, the terms “conductive coating” and “electrode coating” may be used interchangeably to refer to similar concepts and references to a conductive coating herein, in the context of being patterned by selective deposition of an NIC and/or an NPC may, in some non-limiting examples, be applicable to an electrode coating in the context of being patterned by selective deposition of a patterning material. In some non-limiting examples, reference to an electrode coating may signify a coating having a specific composition as described herein. Similarly, in the present disclosure, the terms “deposited material”, “conductive coating material” and “electrode coating material” may be used interchangeably to refer to similar concepts and references to a conductive coating material herein.

In the present disclosure, it will be appreciated by those having ordinary skill in the relevant art that an organic material, may comprise, without limitation, a wide variety of organic molecules, and/or organic polymers. Further, it will be appreciated by those having ordinary skill in the relevant art that organic materials that are doped with various inorganic substances, including without limitation, elements and/or inorganic compounds, may still be considered organic materials. Still further, it will be appreciated by those having ordinary skill in the relevant art that various organic materials may be used, and that the processes described herein are generally applicable to an entire range of such organic materials. Still further, it will be appreciated by those having ordinary skill in the relevant art that organic materials that contain metals and/or other organic elements, may still be considered as organic materials. Still further, it will be appreciated by those having ordinary skill in the relevant art that various organic materials may be molecules, oligomers, and/or polymers.

As used herein, an oligomer generally refers to a material which includes at least two monomer units or monomers. As would be appreciated by a person skilled in the art, an oligomer may differ from a polymer in at least one aspect, including but not limited to: (1) the number of monomer units contained therein; (2) the molecular weight; and (3) other materials properties and/or characteristics. By way of non-limiting example, further description of polymers and oligomers may be found in Naka K. (2014) Monomers, Oligomers, Polymers, and Macromolecules (Overview), and in Kobayashi S., Mullen K. (eds.) Encyclopedia of Polymeric Nanomaterials, Springer, Berlin, Heidelberg.

An oligomer or a polymer generally includes monomer units that are chemically bonded together to form a molecule. Such monomer units may be substantially identical to one another such that the molecule is primarily formed by repeating monomer units, or the molecule may include two or more different monomer units. Additionally, the molecule may include one or more terminal units, which may be different from the monomer units of the molecule. An oligomer or a polymer may be linear, branched, cyclic, cyclo-linear, and/or cross-linked. An oligomer or a polymer may include two or more different monomer units which are arranged in a repeating pattern and/or in alternating blocks of different monomer units.

In the present disclosure, the term “semiconducting layer(s)” may be used interchangeably with “organic layer(s)” since the layers in an OLED device may in some non-limiting examples, may comprise organic semiconducting materials.

In the present disclosure, an inorganic substance may refer to a substance that primarily includes an inorganic material. In the present disclosure, an inorganic material may comprise any material that is not considered to be an organic material, including without limitation, metals, glasses and/or minerals.

In the present disclosure, the terms “photon” and “light” may be used interchangeably to refer to similar concepts. In the present disclosure, photons may have a wavelength that lies in the visible spectrum, in the infrared (IR) region (IR spectrum), near IR region (NIR spectrum), ultraviolet (UV) region (UV spectrum), and/or UVA region (UVA spectrum) (which may correspond to a wavelength range between about 315-400 nm) thereof.

In the present disclosure, the term “visible spectrum” as used herein, generally refers to at least one wavelength in the visible part of the EM spectrum.

In the present disclosure, the term “emission spectrum” as used herein, generally refers to an electroluminescence spectrum of light emitted by an opto-electronic device. By way of non-limiting example, an emission spectrum may be detected using an optical instrument, such as, by way of non-limiting example, a spectrophotometer, which measures an intensity of EM radiation across a wavelength range.

In the present disclosure, the term “onset wavelength” λₒₙₛₑₜ, as used herein, may generally refer to a lowest wavelength at which an emission is detected within an emission spectrum.

In the present disclosure, the term “peak wavelength” λₘₐₓ, as used herein, may generally refer to a wavelength at which a maximum luminous intensity is detected within an emission spectrum.

In some non-limiting examples, the onset wavelength λₒₙₛₑₜ may be less than the peak wavelength λₘₐₓ. In some non-limiting examples, the onset wavelength λₒₙₛₑₜ may correspond to a wavelength at which a luminous intensity is no more than about: 10%, 5%, 3%, 1%, 0.5%, 0.1%, or 0.01%, of the luminous intensity at the peak wavelength λₘₐₓ.

As would be appreciated by those having ordinary skill in the relevant art, such visible part may correspond to any wavelength between about 380-740 nm. In general, electro-luminescent devices may be configured to emit and/or transmit light having wavelengths in a range of between about 425-725 nm, and more specifically, in some non-limiting examples, light having peak emission wavelengths λ_{e max} of 456 nm, 528 nm, and 624 nm, corresponding to B(lue), G(reen), and R(ed) sub-pixels, respectively. Accordingly, in the context of such electro-luminescent devices, the visible part may refer to any wavelength between about 425-725 nm, or between about 456-624 nm. Photons having a wavelength in the visible spectrum may, in some non-limiting examples, also be referred to as “visible light” herein.

In some non-limiting examples, an emission spectrum that lies in the R(ed) part of the visible spectrum may be characterized by a peak wavelength λₘₐₓ that may lie in a wavelength range of about 600-640 nm and in some non-limiting examples, may be substantially about 620 nm.

In some non-limiting examples, an emission spectrum that lies in the G(reen) part of the visible spectrum may be characterized by a peak wavelength λₘₐₓ that may lie in a wavelength range of about 510-540 nm and in some non-limiting examples, may be substantially about 530 nm.

In some non-limiting examples, an emission spectrum that lies in the B(lue) part of the visible spectrum may be characterized by a peak wavelength λₘₐₓ that may lie in a wavelength range of about 450-460 nm and in some non-limiting examples, may be substantially about 455 nm.

In the present disclosure, the term “IR signal” as used herein, may generally refer to EM radiation having a wavelength in an IR subset (IR spectrum) of the EM spectrum. An IR signal may, in some non-limiting examples, have a wavelength corresponding to a near-infrared (NIR) subset (NIR spectrum) thereof. By way of non-limiting examples, an NIR signal may have a wavelength of between about: 750-1400 nm, 750-1300 nm, 800-1300 nm, 800-1200 nm, 850-1300 nm, or 900-1300 nm.

In the present disclosure, the term “absorption spectrum”, as used herein, may generally refer to a wavelength (sub-)range of the EM spectrum over which absorption may be concentrated.

In the present disclosure, the terms “absorption edge”, “absorption discontinuity” and/or “absorption limit” as used herein, may generally refer to a sharp discontinuity in the absorption spectrum of a substance. In some non-limiting examples, an absorption edge may tend to occur at wavelengths where the energy of an absorbed photon may correspond to an electronic transition and/or ionization potential.

In the present disclosure, the term “extinction coefficient” as used herein, may generally refer to the degree to which an EM coefficient is attenuated when propagating through a material. In some non-limiting examples, the extinction coefficient may be understood to correspond to the imaginary component k of a complex refractive index N In some non-limiting examples, the extinction coefficient k of a material may be measured by a variety of methods, including without limitation, by ellipsometry.

In the present disclosure, the terms “refractive index” and/or “index”, as used herein to describe a medium, may refer to a value calculated from a ratio of the speed of light in such medium relative to the speed of light in a vacuum. In the present disclosure, particularly when used to describe the properties of substantially transparent materials, including without limitation, thin film layers and/or coatings, the terms may correspond to the real part, n, in the expression N=n+ik, in which N represents the complex refractive index and k represents the extinction coefficient.

As would be appreciated by those having ordinary skill in the relevant art, substantially transparent materials, including without limitation, thin film layers and/or coatings, may generally exhibit a relatively low k value in the visible spectrum, and therefore the imaginary component of the expression may have a negligible contribution to the complex refractive index, N On the other hand, light-transmissive electrodes formed, for example, by a metallic thin film, may exhibit a relatively low n value and a relatively high k value in the visible spectrum. Accordingly, the complex refractive index, N, of such thin films may be dictated primarily by its imaginary component k.

In the present disclosure, unless the context dictates otherwise, reference without specificity to a refractive index may be intended to be a reference to the real part n of the complex refractive index N.

In some non-limiting examples, there may be a generally positive correlation between refractive index n and transmittance, or in other words, a generally negative correlation between refractive index n and absorption. In some non-limiting examples, the absorption edge of a substance may correspond to a wavelength at which the extinction coefficient k approaches 0.

It will be appreciated that the refractive index n and/or extinction coefficient k values described herein may correspond to such value(s) measured at a wavelength in the visible range of the EM spectrum. In some non-limiting examples, the refractive index n and/or extinction coefficient k value may correspond to the value measured at wavelength(s) of about 456 nm which may correspond to the peak emission wavelength of a B(lue) subpixel, about 528 nm which may correspond to the peak emission wavelength of a G(reen) subpixel, and/or about 624 nm which may correspond to the peak emission wavelength of a R(ed) subpixel. In some non-limiting examples, the refractive index n and/or extinction coefficient k value described herein may correspond to the value measured at a wavelength of about 589 nm, which approximately corresponds to the Fraunhofer D-line.

In the present disclosure, the concept of a pixel may be discussed on conjunction with the concept of at least one sub-pixel thereof. For simplicity of description only, such composite concept may be referenced herein as a “(sub-) pixel” and such term is understood to suggest either or both of a pixel and/or at least one sub-pixel may be thereof, unless the context dictates otherwise.

In some nonlimiting examples, one measure of an amount of a material on a surface may be a percentage coverage of the surface by such material. In some non-limiting examples, surface coverage may be assessed using a variety of imaging techniques, including without limitation, TEM, AFM, and/or SEM.

In the present disclosure, the terms “particle”, “island” and “cluster” may be used interchangeably to refer to similar concepts.

In the present disclosure, for purposes of simplicity of description, the terms “coating film”, “closed coating”, and/or “closed coating”, as used herein, may refer to a thin film structure and/or coating of a conductive coating material used for a conductive coating, in which a relevant part of a surface may be substantially coated thereby, such that such surface may be not substantially exposed by or through the coating film deposited thereon.

In the present disclosure, unless the context dictates otherwise, reference without specificity to a thin film may be intended to be a reference to a substantially closed coating.

In some non-limiting examples, a closed coating, in some non-limiting examples, of a conductive coating and/or a conductive coating material, may be disposed to cover a portion of an underlying surface, such that, within such part, less than about: 40%, 30%, 25%, 20%, 15%, 10%, 5%, 3%, or 1% of the underlying surface therewithin is exposed by or through the closed coating.

Those having ordinary skill in the relevant art will appreciate that a closed coating may be patterned using various techniques and processes, including without limitation, those described herein, so as to deliberately leave a part of the exposed layer surface of the underlying surface to be exposed after deposition of the closed coating. In the present disclosure, such patterned films may nevertheless be considered to constitute a closed coating, if, by way of non-limiting example, the thin film and/or coating that is deposited, within the context of such patterning, and between such deliberately exposed parts of the exposed layer surface of the underlying surface, itself substantially comprises a closed coating.

Those having ordinary skill in the relevant art will appreciate that, due to the inherent variability in the deposition process, and in some non-limiting examples, to the existence of impurities in either or both of the deposited materials, in some non-limiting examples, the conductive coating material, and the exposed layer surface of the underlying material, deposition of a thin film, using various techniques and processes, including without limitation, those described herein, may nevertheless result in the formation of small apertures, including without limitation, pin-holes, tears, and/or cracks, therein. In the present disclosure, such thin films may nevertheless be considered to constitute a closed coating, if, by way of non-limiting example, the thin film and/or coating that is deposited substantially comprises a closed coating and meets any specified percentage coverage criterion set out, despite the presence of such apertures.

In the present disclosure, for purposes of simplicity of description, the term “discontinuous coating” as used herein, may refer to a thin film structure and/or coating of a material used for a conductive coating, in which a relevant part of a surface coated thereby, may be neither substantially devoid of such material, or forms a closed coating thereof. In some non-limiting examples, a discontinuous coating of a conductive coating material may manifest as a plurality of discrete islands disposed on such surface.

In the present disclosure, for purposes of simplicity of description, the result of deposition of vapor monomers onto an exposed layer surface of an underlying material, that has not (yet) reached a stage where a closed coating has been formed, may be referred to as a “intermediate stage layer”. In some non-limiting examples, such an intermediate stage layer may reflect that the deposition process has not been completed, in which such an intermediate stage layer may be considered as an interim stage of formation of a closed coating. In some non-limiting examples, an intermediate stage layer may be the result of a completed deposition process, and thus constitute a final stage of formation in and of itself.

In some non-limiting examples, an intermediate stage layer may more closely resemble a thin film than a discontinuous coating but may have apertures and/or gaps in the surface coverage, including without limitation, one or more dendritic projections, and/or one or more dendritic recesses. In some non-limiting examples, such an intermediate stage layer may comprise a fraction 1/X of a single monolayer of the deposited material such that it does not form a closed coating.

In the present disclosure, for purposes of simplicity of description, the term “dendritic”, with respect to a coating, including without limitation, the conductive coating, may refer to feature(s) that resemble a branched structure when viewed in a lateral aspect. In some non-limiting examples, the conductive coating may comprise a dendritic projection and/or a dendritic recess. In some non-limiting examples, a dendritic projection may correspond to a part of the conductive coating that exhibits a branched structure comprising a plurality of short projections that are physically connected and extend substantially outwardly. In some non-limiting examples, a dendritic recess may correspond to a branched structure of gaps, openings, and/or uncovered parts of the conductive coating that are physically connected and extend substantially outwardly. In some non-limiting examples, a dendritic recess may correspond to, including without limitation, a mirror image and/or inverse pattern, to the pattern of a dendritic projection. In some non-limiting examples, a dendritic projection and/or a dendritic recess may have a configuration that exhibits, and/or mimics a fractal pattern, a mesh, a web, and/or an interdigitated structure.

In some non-limiting examples, sheet resistance may be a property of a component, layer, and/or part that may alter a characteristic of an electric current passing through such component, layer, and/or part. In some non-limiting examples, a sheet resistance of a coating may generally correspond to a characteristic sheet resistance of the coating, measured and/or determined in isolation from other components, layers, and/or parts of the device.

In the present disclosure, a deposited density may refer to a distribution, within a region, which in some non-limiting examples may comprise an area and/or a volume, of a deposited material therein. Those having ordinary skill in the relevant art will appreciate that such deposited density may be unrelated to a density of mass or material within a particle itself that may comprise such deposited material. In the present disclosure, unless the context dictates otherwise, reference to a deposited density, and/or to a density, may be intended to be a reference to a distribution of such deposited material, including without limitation, as at least one particle, within an area.

In some non-limiting examples, a bond dissociation energy of a metal may correspond to a standard-state enthalpy change measured at 298 K from the breaking of a bond of a diatomic molecule formed by two identical atoms of the metal. Bond dissociation energies may, by way of non-limiting example, be determined based on known literature including without limitation, Luo, Yu-Ran, “Bond Dissociation Energies” (2010).

Where features or aspects of the present disclosure are described in terms of Markush groups, it will be appreciated by those having ordinary skill in the relevant art that the present disclosure is also thereby described in terms of any individual member of sub-group of members of such Markush group.

References in the singular form may include the plural and vice versa, unless otherwise noted.

As used herein, relational terms, such as “first” and “second”, and numbering devices such as “a”, “b” and the like, may be used solely to distinguish one entity or element from another entity or element, without necessarily requiring or implying any physical or logical relationship or order between such entities or elements.

The terms “including” and “comprising” may be used expansively and in an open-ended fashion, and thus should be interpreted to mean “including, but not limited to”. The terms “example” and “exemplary” may be used simply to identify instances for illustrative purposes and should not be interpreted as limiting the scope of the invention to the stated instances. In particular, the term “exemplary” should not be interpreted to denote or confer any laudatory, beneficial or other quality to the expression with which it is used, whether in terms of design, performance or otherwise.

Further, the term “critical”, especially when used in the expressions “critical nuclei” “critical nucleation rate”, “critical concentration” “critical cluster”, “critical monomer”, “critical particle size”, and/or “critical surface tension” may be a term familiar to those having ordinary skill in the relevant art, including as relating to or being in a state in which a measurement or point at which some quality, property or phenomenon undergoes a definite change. As such, the term “critical” should not be interpreted to denote or confer any significance or importance to the expression with which it is used, whether in terms of design, performance, or otherwise.

The terms “couple” and “communicate” in any form may be intended to mean either a direct connection or indirect connection through some interface, device, intermediate component or connection, whether optically, electrically, mechanically, chemically, or otherwise.

The terms “on” or “over” when used in reference to a first component relative to another component, and/or “covering” or which “covers” another component, may encompass situations where the first component is direct on (including without limitation, in physical contact with) the other component, as well as cases where one or more intervening components are positioned between the first component and the other component.

Directional terms such as “upward”, “downward”, “left” and “right” may be used to refer to directions in the drawings to which reference is made unless otherwise stated. Similarly, words such as “inward” and “outward” may be used to refer to directions toward and away from, respectively, the geometric center of the device, area or volume or designated parts thereof. Moreover, all dimensions described herein may be intended solely to be by way of example of purposes of illustrating certain embodiments and may not be intended to limit the scope of the disclosure to any embodiments that may depart from such dimensions as may be specified.

As used herein, the terms “substantially”, “substantial”, “approximately” and/or “about” may be used to denote and account for small variations. When used in conjunction with an event or circumstance, such terms may refer to instances in which the event or circumstance occurs precisely, as well as instances in which the event or circumstance occurs to a close approximation. By way of non-limiting example, when used in conjunction with a numerical value, such terms may refer to a range of variation of no more than about ±10% of such numerical value, such as no more than: ±5%, ±4%, ±3%, ±2%, ±1%, ±0.5%, ±0.1%, or ±0.05%.

As used herein, the phrase “consisting substantially of” may be understood to include those elements specifically recited and any additional elements that do not materially affect the basic and novel characteristics of the described technology, while the phrase “consisting of” without the use of any modifier, may exclude any element not specifically recited.

As will be understood by those having ordinary skill in the relevant art, for any and all purposes, particularly in terms of providing a written description, all ranges disclosed herein may also encompass any and all possible sub-ranges and/or combinations of sub-ranges thereof. Any listed range may be easily recognized as sufficiently describing and/or enabling the same range being broken down at least into equal fractions thereof, including without limitation, halves, thirds, quarters, fifths, tenths etc. As a non-limiting example, each range discussed herein may be readily be broken down into a lower third, middle third and/or upper third, etc.

As will also be understood by those having ordinary skill in the relevant art, all language and/or terminology such as “up to”, “at least”, “greater than”, “less than”, and the like, may include and/or refer the recited range(s) and may also refer to ranges that may be subsequently broken down into sub-ranges as discussed herein.

As will be understood by those having ordinary skill in the relevant art, a range includes each individual member of the recited range.

### GENERAL

The purpose of the Abstract is to enable the relevant patent office or the public generally, and specifically, persons of ordinary skill in the art who are not familiar with patent or legal terms or phraseology, to quickly determine from a cursory inspection, the nature of the technical disclosure. The Abstract is neither intended to define the scope of this disclosure, nor is it intended to be limiting as to the scope of this disclosure in any way.

The structure, manufacture and use of the presently disclosed examples have been discussed above. The specific examples discussed are merely illustrative of specific ways to make and use the concepts disclosed herein, and do not limit the scope of the present disclosure. Rather, the general principles set forth herein are considered to be merely illustrative of the scope of the present disclosure.

It should be appreciated that the present disclosure, which is described by the claims and not by the implementation details provided, and which can be modified by varying, omitting, adding or replacing and/or in the absence of any element(s) and/or limitation(s) with alternatives and/or equivalent functional elements, whether or not specifically disclosed herein, will be apparent to those having ordinary skill in the relevant art, may be made to the examples disclosed herein, and may provide many applicable inventive concepts that may be embodied in a wide variety of specific contexts, without straying from the present disclosure.

In particular, features, techniques, systems, sub-systems and methods described and illustrated in one or more of the above-described examples, whether or not described an illustrated as discrete or separate, may be combined or integrated in another system without departing from the scope of the present disclosure, to create alternative examples comprised of a combination or sub-combination of features that may not be explicitly described above, or certain features may be omitted, or not implemented. Features suitable for such combinations and sub-combinations would be readily apparent to persons skilled in the art upon review of the present application as a whole. Other examples of changes, substitutions, and alterations are easily ascertainable and could be made without departing from the spirit and scope disclosed herein.

All statements herein reciting principles, aspects and examples of the disclosure, as well as specific examples thereof, are intended to encompass both structural and functional equivalents thereof and to cover and embrace all suitable changes in technology. Additionally, it is intended that such equivalents include both currently-known equivalents as well as equivalents developed in the future, i.e., any elements developed that perform the same function, regardless of structure.

The present disclosure includes, without limitation, the following clauses:

1 A display panel having a plurality of layers and extending in a first portion and a second portion of at least one lateral aspect defined by a lateral axis, the panel adapted to accept at least one electromagnetic (EM) signal through the second portion, at an angle relative to the layers, for exchange with at least one under-display component, the panel comprising at least one closed coating of a deposited material disposed on an exposed layer surface of the panel in the first portion,

wherein the second portion is substantially devoid of a closed coating of the deposited material.

2 The panel of clause 1, wherein the panel is adapted to mate with a body to form a user device for housing the at least one under-display component therein, wherein the first portion comprises at least one emissive region for emitting the at least one EM signal away from the body.

3 The panel of clause 1 or 2, wherein the at least one under-display component comprises at least one of:

a receiver adapted to receive; and

a transmitter adapted to emit;

the at least one EM signal passing through the panel beyond the user device.

4 The panel of any one of clause 1 through 3, wherein the at least one under-display component comprises a receiver for receiving the at least one EM signal passing through the panel from beyond the user device.

5 The panel of clause 4, wherein the at least one EM signal passing through the panel from beyond the user device emanates from the panel and is reflected by a surface back therethrough.

6 The panel of clause 5, wherein the at least one EM signal emanating from the panel is emitted by at least one of:

the at least one under-display component and passing through a non-emissive region of the panel; and

an emissive region of the panel.

7 The panel of clauses 1 through 6, wherein the at least one under-display component comprises a transmitter adapted to emit the at least one EM signal passing through the panel beyond the user device.

8 A display panel having a plurality of layers and extending in a first portion and a second portion of at least one lateral aspect defined by a lateral axis, the panel adapted to accept at least one electromagnetic (EM) signal through the second portion, at an angle relative to the layers, comprising at least one closed coating of a deposited material disposed on an exposed layer surface of the panel in the first portion,

wherein the second portion is substantially devoid of a closed coating of the deposited material.

9 The panel of clause 8, further comprising a nucleation-inhibiting coating (NIC) on the exposed layer surface of the panel in the second portion, wherein an initial sticking probability for depositing the deposited material onto a surface of the NIC in the first portion is substantially less than at least one of:

0.3, and

the initial sticking probability for depositing the deposited material onto the exposed layer surface.

10 The panel of clause 9, wherein the NIC comprises an NIC material.

11 The panel of clause 9 or 10, wherein at least one of the NIC and the NIC material has an initial sticking probability S0 for the deposited material that is less than at least one of about: 0.9, 0.3, 0.2, 0.15, 0.1, 0.08, 0.05, 0.03, 0.02, 0.01, 0.008, 0.005, 0.003, 0.001, 0.0008, 0.0005, 0.0003, and 0.0001.

12 The panel of clause 9 or 10, wherein at least one of the NIC and the NIC material has an initial sticking probability S0 for at least one of silver (Ag) and magnesium (Mg) that is less than at least one of about: 0.9, 0.3, 0.2, 0.15, 0.1, 0.08, 0.05, 0.03, 0.02, 0.01, 0.008, 0.005, 0.003, 0.001, 0.0008, 0.0005, 0.0003, and 0.0001.

13 The panel of any one of clauses 9 through 11, wherein at least one of the NIC and the NIC material has an initial sticking probability S0 for the deposited material that is between about: 0.15-0.0001, 0.1-0.0003, 0.08-0.0005, 0.08-0.0008, 0.05-0.001, 0.03-0.0001, 0.03-0.0003, 0.03-0.0005, 0.03-0.0008, 0.03-0.001, 0.03-0.005, 0.03-0.008, 0.03-0.01, 0.02-0.0001, 0.02-0.0003, 0.02-0.0005, 0.02-0.0008, 0.02-0.001, 0.02-0.005, 0.02-0.008, 0.02-0.01, 0.01-0.0001, 0.01-0.0003, 0.01-0.0005, 0.01-0.0008, 0.01-0.001. 0.01-0.005, 0.01-0.008, 0.008-0.0001, 0.008-0.0003, 0.008-0.0005, 0.008-0.0008, 0.008-0.001, 0.008-0.005, 0.005-0.0001, 0.005-0.0003, 0.005-0.0005, 0.005-0.0008, and 0.005-0.001.

14 The panel of any one of clauses 9 through 12, wherein the NIC material has an initial sticking probability S0 that is less than at least one threshold value for a plurality of different deposited materials.

15 The panel of clause 14, wherein the plurality of materials is selected from at least one of: silver (Ag), magnesium (Mg), ytterbium (Yb), cadmium (Cd), and zinc (Zn).

16 The panel of clause 14 or 15, wherein the NIC material has an initial sticking probability S0 below a first threshold value for a first one of the plurality of deposited materials and an initial sticking probability S0 for a second one of the plurality of deposited materials.

17 The panel of clause 16, wherein the first threshold is greater than the second threshold value.

18 The panel of any one of clauses 9 through 16, wherein at least one of the NIC and the NIC material has a light transmittance of at least a threshold transmittance value after being subjected to a vapor flux of silver (Ag).

19 The panel of clause 18, wherein the vapor flux is at a vacuum pressure of at least about: 10⁻⁴ Torr and 10⁻⁵ Torr.

20 The panel of clause 18 or 19, wherein the vapor flux has a deposition rate of about 1 angstrom (A)/sec.

21 The panel of any one of clauses 18 through 20, wherein the vapor flux is applied until a reference thickness of 15 nm is reached.

22 The panel of any one of clauses 18 through 21, wherein a surface to which the vapor flux is applied is at a temperature of about 25° C.

23 The panel of any one of clauses 18 through 22, wherein a surface to which the vapor flux is applied is about 65 cm away from an evaporation source of the Ag.

24 The panel of any one of clauses 18 through 23, wherein the threshold transmittance value is selected from at least one of about: 60%, 65%, 70%, 75%, 80%, 85%, and 90%.

25 The panel of any one of clauses 18 through 24, wherein the threshold transmittance value is measured at a wavelength of about 460 nm.

26 The panel of any one of clauses 9 through 25, wherein at least one of the NIC and the NIC material has a surface energy (Y1) that is less than at least one of about: 24 dynes/cm, 20 dynes/cm, 19 dynes/cm, 18 dynes/cm, 17 dynes/cm, 16 dynes/cm, 15 dynes/cm, 14 dynes/cm, 12 dynes/cm, 11 dynes/cm, 10 dynes/cm, 9 dynes/cm, and 8 dynes/cm.

27 The panel of any one of clauses 9 through 26, wherein at least one of the NIC and the NIC material has a surface energy (Y1) that is between about: 13-20 dynes/cm, and 13-19 dynes/cm.

28 The panel of any one of clauses 9 through 27, wherein at least one of the NIC and the NIC material has a refractive index n for photons at a wavelength of 550 nm that is less than at least one of about: 1.55, 1.5, 1.45, 1.43, 1.4, 1.39, 1.38, 1.37, 1.35, 1.32, and 1.3.

29 The panel of any one of clauses 9 through 28, wherein at least one of the NIC and the NIC material has an extinction coefficient k that is less than 0.01 for photons at a wavelength that exceeds at least one of about: 600 nm, 500 nm, 460 nm, 420 nm, and 410 nm.

30 The panel of any one of clauses 9 through 29, wherein at least one of the NIC and the NIC material has an extinction coefficient k that may be greater than about: 0.05, 0.1, 0.2 and 0.5, for photons at a wavelength that is shorter than at least one of about: 400 nm, 390 nm, 380 nm, and 370 nm.

31 The panel of any one of clauses 9 through 30, wherein at least one of the NIC and the NIC material has a glass transition temperature T_{g} that is less than about: 300° C., 150° C., 130° C., 30° C., 0° C., −30° C., and −50° C.

32 The panel of any one of clauses 9 through 31, wherein the NIC material has a sublimation temperature of between about: 100-320° C., 120-300° C., 140-280° C., and 150-250° C.

33 The panel of any one of clauses 9 through 32, wherein at least one of the NIC and the NIC material contains at least one of fluorine (F) and silicon (Sᵢ).

34 The panel of clause 33, wherein the NIC material is a compound that includes F.

35 The panel of clause 34, wherein the NIC material is a compound that includes F and carbon (C).

36 The panel of clause 35, wherein the NIC material comprises F and C in an atomic ratio corresponding to a quotient of F/C of at least one of at least about: 1, 1.5, and 2.

37 The panel of any one of clauses 33 through 36, wherein the NIC material comprises an oligomer.

38 The panel of any one of clauses 33 through 37, wherein the NIC material has a molecular structure comprising a backbone and at least one functional group bonded to the backbone.

39 The panel of clause 38, wherein the NIC material comprises a siloxane group.

40 The panel of clause 38 or 39, wherein the backbone comprises a siloxane group.

41 The panel of any one of clauses 38 through 40, wherein the at least one functional group comprises F.

42 The panel of clause 41, wherein the at least one functional group comprises a fluoroalkyl group.

43 The panel of any one of clauses 38 through 42, wherein the NIC material comprises a silsesquioxane group.

44 The panel of any one of clauses 38 through 43, wherein the NIC material comprises an aryl group.

45 The panel of any one of clauses 38 through 44, wherein the NIC material comprises a hydrocarbon group.

46 The panel of any one of clauses 38 through 45, wherein the NIC material comprises a phosphazene group.

47 The panel of any one of clauses 38 through 46, wherein the NIC material comprises a substituted or unsubstituted, linear, branched or cyclic hydrocarbon group.

48 The panel of clause 47, wherein at least one C atom in the substituted group is substituted by a heteroatom selected from at least one of oxygen (O), nitrogen (N), and sulfur (S).

49 The panel of any one of clauses 38 through 48, wherein the NIC material comprises a fluoropolymer.

50 The panel of any one of clauses 38 through 49, wherein the NIC material comprises a metal complex.

51 The panel of any one of clauses 38 through 50, wherein the NIC material comprises an organic-inorganic hybrid material.

52 The panel of any one of clauses 10 through 51, wherein the NIC material is doped with another material to act as a nucleation site thereon.

53 The panel of any one of clauses 9 through 52, further comprising a high-index medium extending along a surface of the NIC, and wherein the NIC comprises a low-index coating having a refractive index that is less than a refractive index of the high-index medium.

54 The panel of clause 53, wherein the high-index medium comprises a high-index coating.

54 The panel of clause 53 or 54, wherein the high-index medium comprises a covering layer.

55 The panel of clause 53 or 54, wherein the high-index medium comprises lithium fluoride (LiF).

56 The panel of clause 53, wherein the high-index medium comprises an air gap.

57 The panel of any one of clauses 8 through 56, wherein the second portion comprises at least one particle structure comprised of the deposited material.

58 The panel of clause 57, wherein the at least one particle structure forms a discontinuous layer disposed on an exposed layer surface of the NIC.

59 The panel of clause 57 or 58, wherein the second portion comprises a UVA-absorbing layer.

60 The panel of clause 59, wherein the UVA-absorbing layer comprises the at least one particle structure.

61 The panel of any one of clauses 8 through 60, wherein the second portion comprises a UVA-absorbing layer.

62 The panel of clause 61, wherein the UVA-absorbing layer comprises at least one particle structure comprised of the deposited material.

63 The panel of any one of clauses 8 through 62, further comprising a low-index coating disposed on the exposed layer surface of the panel in the second portion and a high-index medium extending along a surface of the low-index coating, wherein a refractive index of the low-index coating is less than a refractive index of the high-index medium.

64 The panel of clause 63, wherein the low-index coating comprises a nucleation-inhibiting coating (NIC) wherein an initial sticking probability for depositing the deposited material onto a surface of the NIC in the first portion is substantially less than at least one of:

0.3, and

the initial sticking probability for depositing the deposited material onto the exposed layer surface.

65 The panel of clause 63 or 64, wherein the high-index medium comprises a high-index coating.

66 The panel of any one of clauses 63 through 65, wherein the high-index medium comprises a covering layer.

67 The panel of any one of clauses 63 through 66, wherein the high-index medium comprises lithium fluoride (LiF).

68 The panel of clause 63 or 64, wherein the high-index medium comprises an air gap.

69 The panel of any one of clauses 8 through 68, wherein the exposed layer surface of the panel in the first portion is of an underlying coating that extends substantially continuously across both the first portion and the second portion.

70 The panel of any one of clauses 8 through 69, wherein the exposed layer surface of the panel is substantially co-planar and co-existent with the exposed layer surface of the EM panel in the second portion.

71 The panel of any one of clauses 8 through 70, wherein the at least one closed coating substantially inhibits transmission of an EM signal therethrough an angle relative to the layers.

72 The panel of any one of clauses 8 through 71, wherein the second portion is substantially devoid of any feature that substantially inhibits transmission of an EM signal therethrough at an angle relative to the layers.

73 The panel of any one of clauses 8 through 72, wherein the deposited material is substantially conductive.

74 The panel of any one of clauses 8 through 73, wherein an average film thickness of the at least one closed coating is between about 5-80 nm.

75 The panel of any one of clauses 8 through 74, wherein the first portion comprises at least one emissive region for emitting an EM signal at an angle relative to the layers.

76 The panel of clause 75, further comprising:

a substrate; and

at least one semiconducting layer disposed thereon; and wherein:

each emissive region comprises a first electrode and a second electrode,

the first electrode is disposed between the substrate and the at least one semiconducting layer, and

the at least one semiconducting layer is disposed between the first electrode and the second electrode

77 The panel of clause 76, wherein the second electrode comprises the at least one closed coating of the deposited material.

78 The panel of clause 76 or 77, wherein the exposed layer surface of the panel is an exposed layer surface of the at least one semiconducting layer.

79 The panel of any one of clauses 76 through 78, wherein the substrate extends substantially continuously across both the first portion and the second portion.

80 The panel of clause 79, wherein the at least one semiconducting layer extends substantially continuously across both the first portion and the second portion.

81 The panel of any one of clauses 76 through 80, wherein the first portion comprises a plurality of emissive regions.

82 The panel of clause 81, wherein the first portion comprises at least one non-emissive region between adjacent emissive regions.

83 The panel of any one of clauses 876 through 82 wherein the second portion is substantially devoid of any emissive regions.

84 The panel of any one of clauses 8 through 83, further comprising at least one covering layer disposed on an exposed layer surface of the at least one closed coating in the first portion and on an exposed layer surface of the panel in the second portion.

85 The panel of clause 84, wherein the at least one covering layer is selected from at least one of: a barrier coating, glass cap, thin film encapsulation (TFE) layer, polarizer, optically clear adhesive (OCA), touchscreen material, glass covering, and any combination of any of these.

86 A user device comprising:

a display panel having a plurality of layers and extending in a first portion and a second portion of at least one lateral aspect defined by a lateral axis; and

at least one under-display component adapted to exchange at least one electromagnetic (EM) signal through the second portion of the panel at an angle relative to the layers;

wherein the panel comprises at least one closed coating of a deposited material disposed on an exposed layer surface of the panel in the first portion; and

wherein the second portion is substantially devoid of a closed coating of the deposited coating.

Accordingly, the specification and the examples disclosed therein are to be considered illustrative only, with a true scope of the disclosure being disclosed by the following numbered claims:

1. A display panel having a plurality of layers and extending in a first portion and a second portion of at least one lateral aspect defined by a lateral axis, the panel adapted to accept at least one electromagnetic (EM) signal through the second portion, at an angle relative to the layers, for exchange with at least one under-display component, the panel comprising at least one closed coating of a deposited material disposed on an exposed layer surface of the panel in the first portion;
wherein the second portion is substantially devoid of a closed coating of the deposited material.

2. The panel of claim 1, wherein the at least one under-display component comprises at least one of:
a receiver adapted to receive; and
a transmitter adapted to emit;
the at least one EM signal passing through the panel beyond the user device.

3. A display panel having a plurality of layers and extending in a first portion and a second portion of at least one lateral aspect defined by a lateral axis, the panel adapted to accept at least one electromagnetic (EM) signal through the second portion, at an angle relative to the layers, comprising at least one closed coating of a deposited material disposed on an exposed layer surface of the panel in the first portion;
wherein the second portion is substantially devoid of a closed coating of the deposited material.

4. The panel of claim 3, further comprising a nucleation-inhibiting coating (NIC) on the exposed layer surface of the panel in the second portion, wherein an initial sticking probability for depositing the deposited material onto a surface of the NIC in the first portion is substantially less than at least one of:
0.3, and
the initial sticking probability for depositing the deposited material onto the exposed layer surface.

5. The panel of claim 3, wherein the second portion comprises at least one particle structure comprised of the deposited material.

6. The panel of claim 3, wherein the second portion comprises a UVA-absorbing layer.

7. The panel of claim 3, further comprising a low-index coating disposed on the exposed layer surface of the panel in the second portion and a high-index medium extending along a surface of the low-index coating, wherein a refractive index of the low-index coating is less than a refractive index of the high-index medium.

8. The panel of claim 3, wherein the deposited material comprises at least one of silver (Ag) and ytterbium (Yb).

9. The panel of claim 3, wherein an average film thickness of the at least one closed coating is between about 5-80 nm.

10. The panel of claim 3, wherein the first portion comprises at least one emissive region for emitting an EM signal at an angle relative to the layers.

11. The panel of claim 10, further comprising:
a substrate; and
at least one semiconducting layer disposed thereon; and
wherein:
each emissive region comprises a first electrode and a second electrode,
the first electrode is disposed between the substrate and the at least one semiconducting layer, and
the at least one semiconducting layer is disposed between the first electrode and the second electrode.

12. The panel of claim 11, wherein the second electrode comprises the at least one closed coating of the deposited material.

13. The panel of claim 11, wherein the exposed layer surface of the panel is an exposed layer surface of the at least one semiconducting layer.

14. The panel of claim 11, wherein the substrate extends substantially continuously across both the first portion and the second portion.

15. The panel of claim 14, wherein the at least one semiconducting layer extends substantially continuously across both the first portion and the second portion.

16. The panel of claim 11, wherein the first portion comprises a plurality of emissive regions.

17. The panel of claim 16, wherein the first portion comprises at least one non-emissive region between adjacent emissive regions.

18. The panel of claim 11, wherein the second portion is substantially devoid of any emissive regions.

19. The panel of claim 4, further comprising at least one covering layer disposed on an exposed layer surface of the at least one closed coating in the first portion and on an exposed layer surface of the panel in the second portion.

20. A user device comprising:
a display panel having a plurality of layers and extending in a first portion and a second portion of at least one lateral aspect defined by a lateral axis; and
at least one under-display component adapted to exchange at least one electromagnetic (EM) signal through the second portion of the panel at an angle relative to the layers;
wherein the panel comprises at least one closed coating of a deposited material disposed on an exposed layer surface of the panel in the first portion; and
wherein the second portion is substantially devoid of a closed coating of the deposited coating.
